(19) United States
(12) Patent Application Publication
(10) Pub. No.: US 2026/0047389 A1
(43) Pub. Date: Feb. 12, 2026

(54) APPARATUS FOR WAFER HANDLING AND ALIGNMENT

(71) Applicant: n&k Technology, Inc., San Jose, CA (US)

(72) Inventor: Victor Wai-Cheong LEE, Dublin, CA (US)

(21) Appl. No.: 18/799,839

(22) Filed: Aug. 9, 2024

(51) Int. Cl. H01L 21/68; B25J 9/10; B25J 11/00; B25J 13/08; B25J 15/06; B25J 19/00; H01L 21/687

(52) U.S. Cl. CPC H01L 21/681; B25J 9/101; B25J 11/0095; B25J 15/0616; H01L 21/68707; B25J 13/088; B25J 19/0004

(57) ABSTRACT

Described is an apparatus for wafer handling and alignment. The apparatus can be used for at least handling and aligning wafers for subsequent processing by inspection stations or metrology instruments. The apparatus can include at least an end effector module, a pluck module, an alignment module, a chuck module, and a controller module.

### BACKGROUND

Space can be limited in semiconductor manufacturing environments such as a semiconductor clean room or a fabrication facility. In such space-constrained areas, a size of processing equipment or instruments can be important. Typical industrial robots, e.g., selective compliance assembly robot arms (SCARA) robots, may have sizes or footprints that are unsuitable in such space-constrained areas or are incapable of being integrated into processing equipment or instruments. For example, typical industrial robots may be incompatible when used for handling or positioning wafers between various stations such as, e.g., wafer cassettes, wafer indexers, wafer alignment stations, buffer stations, process stations, and the like.

Accordingly, there is an unmet need for smaller automated apparatuses for handling, positioning, or aligning wafers in space-constrained areas of semiconductor manufacturing environments.

### SUMMARY

The present disclosures describes an apparatus, which can provide technical solutions for handling, positioning, or aligning wafers in space-constrained areas of semiconductor manufacturing environments. For example, the apparatus herein can solve a technical challenge of rotating a wafer to a desired orientation before the wafer is measured (e.g., metrology) or processed by an inspection or a processing platform. In optical metrology, for example, new applications such as Silicon Photonics (SP) and Co-Packaged Optics (CPO) chips may rely on grating arrays and waveguide structures that can have more than one orientation. The apparatus herein can precisely rotate a wafer prior to or during measurements of the grating arrays or waveguide structures.

In an aspect, disclosed herein is an apparatus for positioning a wafer, the apparatus comprising: an end effector module configured to retrieve the wafer from an indexer, wherein the wafer comprises an alignment feature; a pluck module configured to (i) receive the wafer from the end effector module and (ii) rotate the wafer to a predetermined orientation; an alignment module configured to use the alignment feature to determine a virtual center of the wafer during rotation of the wafer by the pluck module; a chuck module configured to releasably hold the wafer after retrieval from the pluck module at the predetermined orientation of the wafer; a stage module operatively coupled to at least the chuck module, wherein the stage module is configured to move the chuck module proximate to an inspection station based at least on using the virtual center of the wafer; and a controller module configured to control at least the end effector module, the pluck module, the chuck module, and the stage module for positioning the wafer.

In some embodiments, the end effector module comprises: an end effector configured to releasably hold the wafer using a pattern of vacuum grooves operatively coupled to a vacuum source; an end effector arm configured to mechanically couple the end effector to the apparatus; a stepper motor operatively coupled the end effector arm and configured to rotate the end effector via the arm; one or more limit switches configured to limit rotation of the end effector to (i) a predetermined upper limit, (ii) a predetermined lower limit, or (iii) a predetermined intermediate limit; and a controller module configured to collectively operate the end effector, the end effector arm, the stepper motor, the one or more limit switches, or any combination thereof. In some embodiments, a vacuum module is configured to control the vacuum source to adjust a vacuum pressure to the pattern of vacuum grooves based at least on a size of the wafer. In some embodiments, a tip of the end effector has a thickness of at most about 3.0 mm, 2.5 mm, 2.0 mm, 1.5 mm, or less.

In some embodiments, the pluck module comprises: a pluck configured to releasably hold the wafer using a pattern of vacuum grooves operatively coupled to a vacuum source; a first motor and shaft coupled thereto configured to rotate the pluck around an axis normal to the stage module; a second motor and shaft coupled thereto configured to translate the pluck along the axis normal to the stage module; one or more limit switches configured to limit movement of the pluck to (i) a predetermined upper limit, (ii) a predetermined lower limit, or (iii) a predetermined intermediate position; a brake configured to stop the translation of the pluck along the axis normal to the stage module; and a controller module configured to collectively operate the pluck, the first motor, the second motor, the one or more limit switches, the brake, the vacuum source, or any combination thereof. In some embodiments, the apparatus further comprises one or more linear side carriages and one or more linear side rails configured to collectively constraint translation of the pluck along the axis normal to the stage module. In some embodiments, the first motor is a stepper motor configured with an embedded rotary incremental non-commutation encoder. In some embodiments, the second motor is a stepper motor. In some embodiments, a vacuum module is configured to control the vacuum source to adjust a vacuum pressure to the pattern of vacuum grooves based at least on a size of the wafer. In some embodiments, the pluck is configured to (i) operate inside a central portion of the chuck module, (ii) extend beyond a plane of the chuck module, (iii) retract to or below the plane of the chuck module, or (iv) any combination of (i)-(iii). In some embodiments, the pluck is configured to rotate the wafer proximate to the alignment module for obtaining an alignment of the wafer. In some embodiments, the pluck is configured to: translate along a central vertical axis of the chuck module; and rotate around the central vertical axis of the chuck module. In some embodiments, the pluck is concentrically aligned along a central vertical axis of the chuck module. In some embodiments, the pluck module is configured to be interchangeable with another pluck module of the same type.

In some embodiments, the alignment module comprises: an optical sensor configured to detect the alignment feature; and a controller module configured to use at least the alignment feature for determining the virtual center of the wafer, wherein at least the virtual center of the wafer is used to align the wafer to the inspection station. In some embodiments, the optical sensor comprises a photoelectric sensor. In some embodiments, the alignment module is configured to be interchangeable with another alignment module of the same type.

In some embodiments, the chuck module comprises: a chuck configured to releasably hold the wafer using a pattern of independently addressable vacuum grooves operatively coupled to a vacuum source; and a controller module configured to collectively operate the chuck and the vacuum source. In some embodiments, a vacuum module is configured to control the vacuum source to adjust a vacuum pressure to each pattern of the pattern of independently addressable vacuum grooves based at least on a size of the wafer. In some embodiments, a diameter of the chuck is equal to or greater than a diameter of the wafer. In some embodiments, the chuck is (i) rotationally fixed relative to a vertical axis of the stage module, (ii) translationally fixed relative to a plane of the stage module, or both (i) and (ii). In some embodiments, the chuck module is configured to be interchangeable with another chuck module of the same type.

In some embodiments, the stage module comprises: a first stage and a motor coupled thereto configured to the translate the apparatus along a first axis of the apparatus; a second stage and a motor coupled thereto configured to translate the apparatus along a second axis of the apparatus; and a controller module configured to collectively move the apparatus along the first axis and the second axis thereby moving the apparatus along a motion path between the indexer, the alignment module, and the inspection station.

In some embodiments, the apparatus further comprises a power module configured to power the apparatus. In some embodiments, the apparatus further comprises a graphical user interface (GUI) configured to allow a user to (i) train the apparatus to move along one or more motion paths between one or more positions or (ii) manually control the apparatus to move along the one or more motion paths between the one or more positions. In some embodiments, the inspection station is configured to perform metrology comprising thin film measurements or critical dimension measurements. In some embodiments, the indexer comprises a standard mechanical interface (SMIF) indexer. In some embodiments, the wafer comprises a fabricated pattern of grating arrays having more than one orientation of the arrays. In some embodiments, aligning the wafer comprises aligning the wafer to an orientation of the arrays. In some embodiments, the wafer comprises a fabricated pattern of waveguide structures having more than one orientation of the structures. In some embodiments, aligning the wafer comprises aligning the wafer to an orientation of the structures. In some embodiments, the alignment feature comprises a flat of the wafer or a notch of the wafer. In some embodiments, the apparatus is configured to align the wafer having a thickness of at most about 2.0 millimeters (mm), 1.5 mm, 1.0 mm, 0.5 mm, or less. In some embodiments, the apparatus is configured to align the wafer having a variation in thickness across a surface of the wafer of at most about 200 micrometers (μm), 150 μm, 100 μm, 50 μm, or less. In some embodiments, the apparatus is configured to fit inside a portion of the inspection station.

In another aspect, disclosed herein is a system, comprising: an end effector module; a chuck module; and a pluck module circumscribed by the chuck module, wherein the pluck module is configured to extend away from and retract towards a plane comprising a surface of the chuck module, wherein the end effector module is configured to direct a wafer to the pluck module after the pluck module is extended away from or above the plane, wherein the pluck module is configured to retract towards or below the plane to bring the wafer in contact with the surface of the chuck module, and wherein the chuck module is configured to permit inspection of the wafer when the wafer is in contact with the surface of the chuck module. In some embodiments, the system further comprises an alignment module configured to determine a virtual center of the wafer. In some embodiments, the system further comprises a stage module configured to move at least the chuck module proximate to an inspection station based at least on using the virtual center of the wafer. In some embodiments, the system further comprises a controller module configured to control at least the end effector module, the chuck module, the pluck module, and the stage module.

In an another aspect, disclosed herein is a method, comprising: (a) providing (1) an end effector module holding a wafer, (2) a chuck module, and (3) a pluck module circumscribed by the chuck module; (b) with the pluck module extended away from a plane comprising a surface of the chuck module, transferring the wafer from the end effector module to the pluck module; (c) retracting the pluck module towards the plane such that the wafer comes in contact with the surface of the chuck module; and (d) with the wafer in contact with the chuck module, inspecting the wafer.

In an another aspect, disclosed herein is a computer program product for positioning a wafer, the computer program product comprising at least one non-transitory computer-readable medium having computer-readable program code portions embodied therein, the computer-readable program code portions comprising: an executable portion for controlling an end effector module configured to retrieve the wafer from an indexer, wherein the wafer comprises an alignment feature; an executable portion for controlling a pluck module configured to (i) receive the wafer from the end effector module and (ii) rotate the wafer to a predetermined orientation; an executable portion for controlling an alignment module configured to use the alignment feature to determine a virtual center of the wafer during rotation of the wafer by the pluck module; an executable portion for controlling a chuck module configured to releasably hold the wafer after retrieval from the pluck module at the predetermined orientation of the wafer; and an executable portion for controlling a stage module operatively coupled to at least the chuck module, wherein the stage module is configured to move the chuck module proximate to an inspection station based at least on using the virtual center of the wafer.

Additional aspects and advantages of the present disclosure will become readily apparent from the following detailed description, wherein only illustrative embodiments of the present disclosure are shown and described. As will be realized, the present disclosure is capable of other and different embodiments, and its several details are capable of modifications in various obvious respects, all without departing from the present disclosure. Accordingly, the drawings and description are to be regarded as illustrative in nature and not as restrictive.

### Incorporation by Reference

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the present disclosure contained in the specification, the specification is intended to supersede and/or take precedence over any such contradictory material.

### BRIEF DESCRIPTION OF THE DRAWINGS

The novel features of the present disclosure are set forth with particularity in the appended claims. A better understanding of the features and advantages of the present disclosure will be obtained by reference to the following detailed description that sets forth illustrative embodiments, in which the principles of the present disclosure are utilized, and the accompanying drawings of which:

FIGS. 1A-1B illustrate the apparatus in different configurations or views for handling or positioning a wafer, in accordance with some embodiments. FIG. 1A illustrates a perspective view of the apparatus, which can include certain features described herein. FIG. 1B illustrates another perspective view of the apparatus, which can include certain features described herein;

FIG. 2 illustrates a perspective view of the apparatus without the stage module, which can include certain features described herein, in accordance with some embodiments;

FIGS. 3A-3B illustrate the apparatus in different configurations or views with one or more covers removed for handling or positioning a wafer, in accordance with some embodiments. FIG. 3A illustrates a perspective view of the apparatus, which can include certain features described herein. FIG. 3B illustrates another perspective view of the apparatus, which can include certain features described herein;

FIGS. 4A-4C illustrate the pluck module of the apparatus in different configurations or views for handling or positioning a wafer, in accordance with some embodiments. FIG. 4A illustrates a perspective view of the pluck module in its lowest position, which can include certain features described herein. FIG. 4B illustrates another perspective view of the pluck module in its lowest position, which can include certain features described herein. FIG. 4C illustrates another perspective view of the pluck module in its highest position, which can include certain features described herein;

FIGS. 5A-5D illustrate the pluck module of the apparatus in different configurations or views for handling or positioning a wafer, in accordance with some embodiments. FIG. 5A illustrates a cross-sectional view of the pluck module in its highest position, which can include certain features described herein. FIG. 5B illustrates another cross-sectional view of the pluck module in its lowest position, which can include certain features described herein. FIG. 5C illustrates another cross-sectional view of the pluck module in its highest position, which can include certain features described herein. FIG. 5D illustrates another cross-sectional view of the pluck module in its lowest position, which can include certain features described herein;

FIGS. 6A-6D illustrate the pluck of the pluck module of the apparatus in different configurations or views for handling or positioning a wafer, in accordance with some embodiments. FIG. 6A illustrates a perspective view of the pluck, which can include certain features described herein. FIG. 6B illustrates another perspective view of the pluck, which can include certain features described herein. FIG. 6C illustrates a plan view (top view) of the pluck, which can include certain features described herein. FIG. 6D illustrates a cross-sectional view of the pluck, which can include certain features described herein;

FIGS. 7A-7G illustrate the chuck module of the apparatus in different configurations or views for handling or positioning a wafer, in accordance with some embodiments. FIG. 7A illustrates a perspective view of the chuck module, which can include certain features described herein. FIG. 7B illustrates another perspective view of the chuck module, which can include certain features described herein. FIG. 7C illustrates another perspective view of the chuck module, which can include certain features described herein. FIG. 7D illustrates a plan view (top view) of the chuck module, which can include certain features described herein. FIG. 7E illustrates another plan view (side view) of the chuck module, which can include certain features described herein. FIG. 7F illustrates another plan view (opposite side view) of the chuck module, which can include certain features described herein. FIG. 7G illustrates another plan view (bottom view) of the chuck module, which can include certain features described herein;

FIGS. 8A-8F illustrate the end effector and the end effector arm of the end effector module of the apparatus in different configurations or views for handling or positioning a wafer, in accordance with some embodiments. FIG. 8A illustrates a perspective view of the end effector and the end effector arm, which can include certain features described herein. FIG. 8B illustrates another perspective view of the end effector and the end effector arm, which can include certain features described herein. FIG. 8C illustrates a plan view (top view) of the end effector and the end effector arm, which can include certain features described herein. FIG. 8D illustrates another plan view (bottom view) of the end effector and the end effector arm, which can include certain features described herein. FIG. 8E illustrates another perspective view of the end effector and the end effector arm, which can include certain features described herein. FIG. 8F illustrates another plan view (side view) of the end effector and the end effector arm, which can include certain features described herein;

FIGS. 9A-9C illustrate the alignment module of the apparatus in different configurations or views for handling or positioning a wafer, in accordance with some embodiments. FIG. 9A illustrates a perspective view of the alignment module for handling or positioning a 100 millimeter (mm) wafer, which can include certain features described herein. FIG. 9B illustrates a plan view (side view) of the alignment module for handling or positioning a 100 mm wafer, which can include certain features described herein. FIG. 9C illustrates another plan view (top view) of the alignment module for handling or positioning a 100 mm wafer, which can include certain features described herein;

FIGS. 10A-10C illustrate the alignment module of the apparatus in different configurations or views for handling or positioning a wafer, in accordance with some embodiments. FIG. 10A illustrates a perspective view of the alignment module for handling or positioning a 150 millimeter (mm) wafer, which can include certain features described herein. FIG. 10B illustrates a plan view (side view) of the alignment module for handling or positioning a 150 mm wafer, which can include certain features described herein. FIG. 10C illustrates another plan view (top view) of the alignment module for handling or positioning a 150 mm wafer, which can include certain features described herein;

FIGS. 11A-11C illustrate the alignment module of the apparatus in different configurations or views for handling or positioning a wafer, in accordance with some embodiments. FIG. 11A illustrates a perspective view of the alignment module for handling or positioning a 200 millimeter (mm) wafer, which can include certain features described herein. FIG. 11B illustrates a plan view (side view) of the alignment module for handling or positioning a 200 mm wafer, which can include certain features described herein. FIG. 11C illustrates another plan view (top view) of the alignment module for handling or positioning a 200 mm wafer, which can include certain features described herein;

FIGS. 12A-12C illustrate a station, e.g., an indexer, operatively coupled to the apparatus in different configurations or views for handling or positioning a wafer, in accordance with some embodiments. In some cases, the indexer can include a standard mechanical interface (SMIF) indexer. FIG. 12A illustrates a plan view (top view) of the indexer operatively coupled to the apparatus for handling or positioning a 100 millimeter (mm) wafer, which can include certain features described herein. FIG. 12B illustrates another plan view (top view) of the indexer operatively coupled to the apparatus for handling or positioning a 150 mm wafer, which can include certain features described herein. FIG. 12C illustrates another plan view (top view) of the indexer operatively coupled to the apparatus for handling or positioning a 200 mm wafer, which can include certain features described herein;

FIGS. 13A-13E illustrate graphical user interfaces (GUIs) of the apparatus to train or operate the apparatus to handle or position a wafer, in accordance with some embodiments. FIG. 13A illustrates a GUI for operating the apparatus, which can include certain features described herein. FIG. 13B illustrates a GUI for training the apparatus, which can include certain features described herein. FIG. 13C illustrates a GUI for training the apparatus, which can include macros or functions described herein. FIG. 13D illustrates a GUI for training the apparatus, which can include low-level commands described herein. FIG. 13E illustrates a GUI for training the apparatus, which can include low-level commands for specific macros or functions described herein.

FIG. 14 illustrates a graphical user interface (GUI) of the apparatus to display or determine an alignment of a wafer, in accordance with some embodiments.

FIG. 15 illustrates a graphical user interface (GUI) of the apparatus to train or operate the stage module of the apparatus for handling or positioning a wafer, in accordance with some embodiments.

FIG. 16 illustrates a non-limiting example of a computing device configured to perform systems and methods described herein, in accordance with some embodiments;

FIG. 17 illustrates a non-limiting example of a web or mobile application provision system configured to perform systems and methods described herein, in accordance with some embodiments; and

FIG. 18 illustrates a non-limiting example of a cloud-based web or mobile application provision system configured to perform systems and methods described herein, in accordance with some embodiments.

### DETAILED DESCRIPTION

While various embodiments of the present disclosure have been shown and described herein, such embodiments are provided by way of example only. Numerous variations, changes, or substitutions may occur without departing from the present disclosure. It should be understood that various alternatives to the embodiments of the present disclosure described herein may be employed. Introduction In an aspect, disclosed herein is an apparatus 100 for positioning a wafer. In some embodiments, the apparatus 100 comprises an end effector module 400 configured to retrieve the wafer from an indexer 1000. In some embodiments, the wafer comprises an alignment feature. In some embodiments, the apparatus 100 comprises a pluck module 200 configured to (i) receive the wafer from the end effector module 400 and (ii) rotate the wafer to a predetermined orientation. In some embodiments, the apparatus 100 comprises an alignment module 600 configured to use the alignment feature to determine a virtual center of the wafer during rotation of the wafer by the pluck module 200. In some embodiments, the apparatus 100 comprises a chuck module 300 configured to releasably hold the wafer after retrieval from the pluck module 200 at the predetermined orientation of the wafer. In some embodiments, the apparatus 100 comprises a stage module 500 operatively coupled to at least the chuck module 300. In some embodiments, the stage module 500 is configured to move the chuck module 300 proximate to an inspection station based at least on using the virtual center of the wafer. In some embodiments, the apparatus 100 comprises a controller module 250 and 450 configured to control at least the end effector module 400, the pluck module 200, the chuck module 300, and the stage module 500 for positioning the wafer.

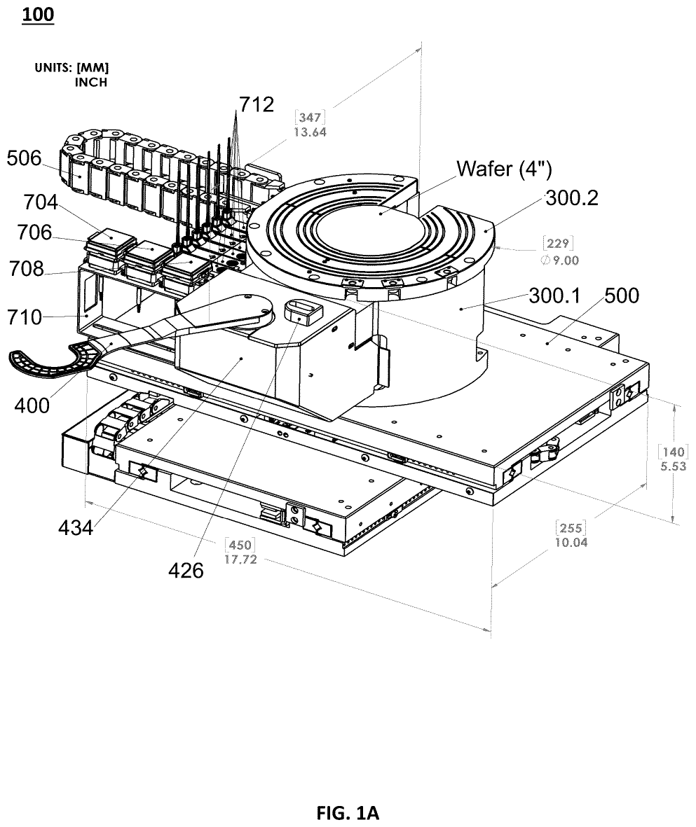

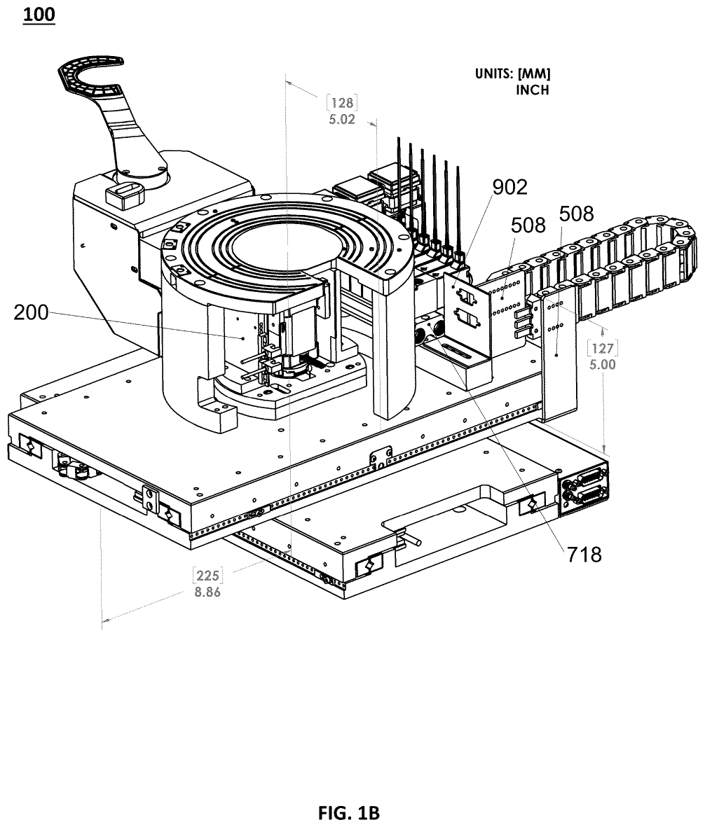

FIGS. 1A-1B illustrate the apparatus 100 in different configurations or views for handling or positioning a wafer. FIG. 1A illustrates a perspective view of the apparatus 100, which can be configured to include: the chuck module 300, the end effector module 400, and the stage module 500. As depicted in FIG. 1A, the chuck module 300 can be configured to include a wafer chuck support 300.1 and a wafer chuck top 300.2. The end effector module 400 can be configured to include a front cover 434 and an end effector hard stop 426. The stage module 500 can include an energy chain 506. The vacuum module 700 can be configured to include a vacuum gauge 704 for the end effector module 400, a vacuum gauge 706 for the pluck module 200, and a vacuum gauge 708 for the chuck module 300. The vacuum gauges 704-708 can be mounted to the apparatus 100 using a mount 710. The vacuum module 700 can be configured with a solenoid 712 for control of vacuum pressure to each of the end effector module 400, the pluck module 200, and chuck module 300. In some cases, the apparatus 100 can be configured to handle or position a 100 millimeter (mm) wafer.

FIG. 1B illustrates another perspective view of the apparatus 100, which can be configured to include: the stage module 500, the pluck module 200, the vacuum module 700, and the power module 900. As depicted in FIG. 1B, the stage module 500 can be configured with energy chain mounts 508 for mounting the energy chain 506 to the apparatus 100. The vacuum module 700 can be configured with a vacuum manifold 718. The power module 900 can be configured with a power connector mount 902 for electrically coupling the power module 900 to the apparatus 100.

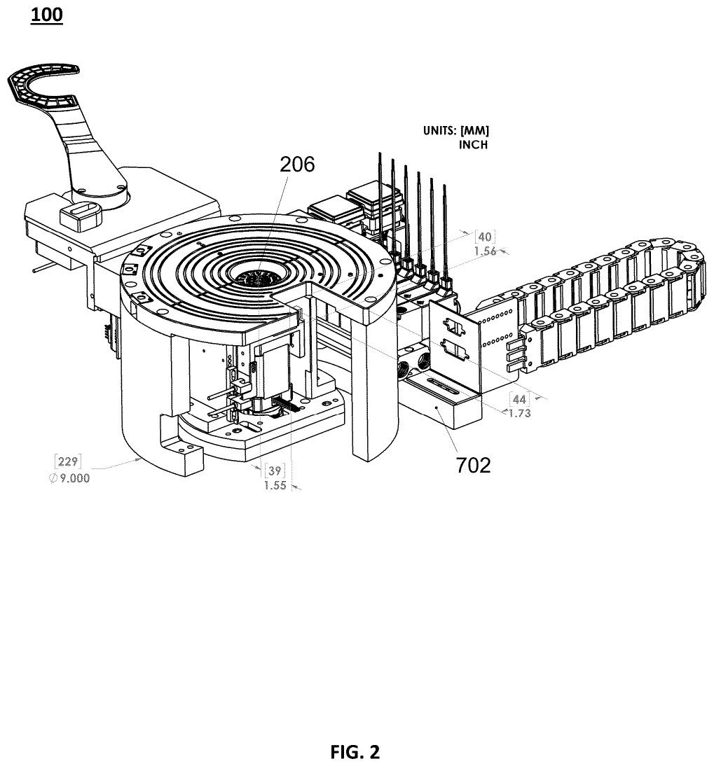

FIG. 2 illustrates a perspective view of the apparatus 100 without the stage module 500 for handling or positioning a wafer. As depicted in FIG. 2, the pluck module 200 can be configured to include the pluck 206. The vacuum manifold 718 of the vacuum module 700 can be configured with a base mount 702 for mounting the vacuum manifold 718 to the apparatus 100. The power connector mount 902 can be configured with a base mount 702 for mounting the power connector mount 902 to the apparatus 100.

In some cases, apparatus 100 can be integrated into or coupled with an inspection station. In some cases, the inspection station may perform measurements (e.g., optical measurements or metrology) on a wafer. For example, measurements can include thin film measurements, e.g., thickness measurements of single and multi-layer film stacks. In some cases, measurements can include scatterometry-related measurements, e.g., optical critical dimension (CD) measurements. For example, optical CD measurements can include critical trench measurements, top and bottom CD measurements, hard mask and sidewall oxide thickness measurements. In some cases, measurements can include stress measurements and microscopic defects measurements.

While preferred embodiments of sizes and dimensions of the apparatus 100 have been shown in the figures herein, such sizes and dimensions are provided by way of example only. It is not intended that the present disclosure be limited by the specific examples of sizes and dimensions provided within the figures. While the present disclosure has been described with reference to the aforementioned figures, the descriptions and illustrations of the embodiments herein are not meant to be construed in a limiting sense. Numerous variations, changes, and substitutions may occur without departing from the present disclosure.

### End Effector Module

The apparatus 100 can be configured with an end effector module 400. In some embodiments, the end effector module 400 comprises an end effector 400.2 configured to releasably hold the wafer using a pattern of vacuum grooves 406 or 408 operatively coupled to a vacuum source. In some embodiments, the end effector module 400 comprises an end effector arm 400.4 configured to mechanically couple the end effector 400.2 to the apparatus 100. In some embodiments, the end effector module 400 comprises a stepper motor 432 operatively coupled the end effector arm 400.4 and configured to rotate the end effector 400.2 via the arm 400.4. In some embodiments, the end effector module 400 comprises one or more limit switches 430 configured to limit rotation of the end effector 400.2 to (i) a predetermined upper limit, (ii) a predetermined lower limit, or (iii) a predetermined intermediate limit. In some embodiments, the end effector module 400 comprises a controller module 450 configured to collectively operate the end effector 400.2, the end effector arm 400.4, the stepper motor 432, the one or more limit switches 430, or any combination thereof. In some embodiments, a vacuum module 700 is configured to control the vacuum source to adjust a vacuum pressure to the pattern of vacuum grooves 408 based at least on a size of the wafer. In some embodiments, a tip of the end effector 400.2 has a thickness of at most about 3.0 millimeters (mm), 2.5 mm, 2.0 mm, 1.5 mm, or less.

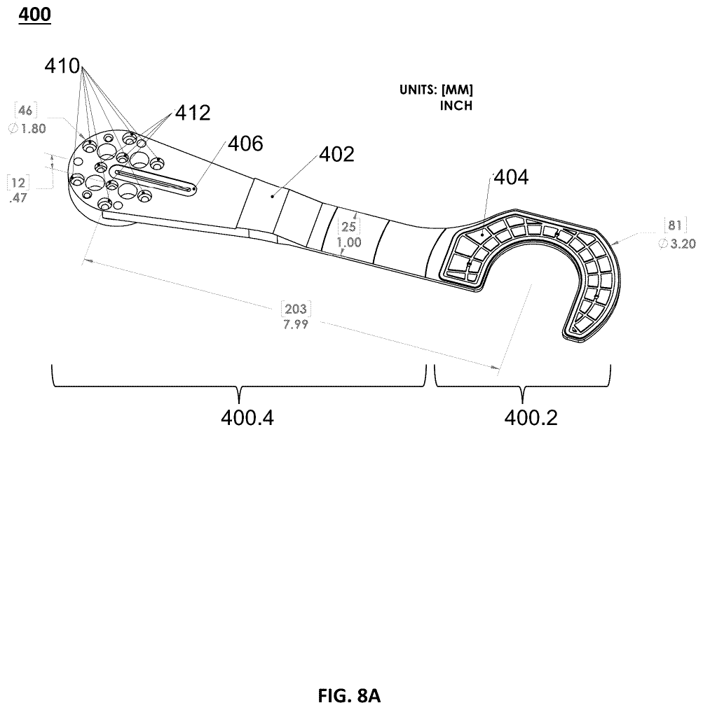

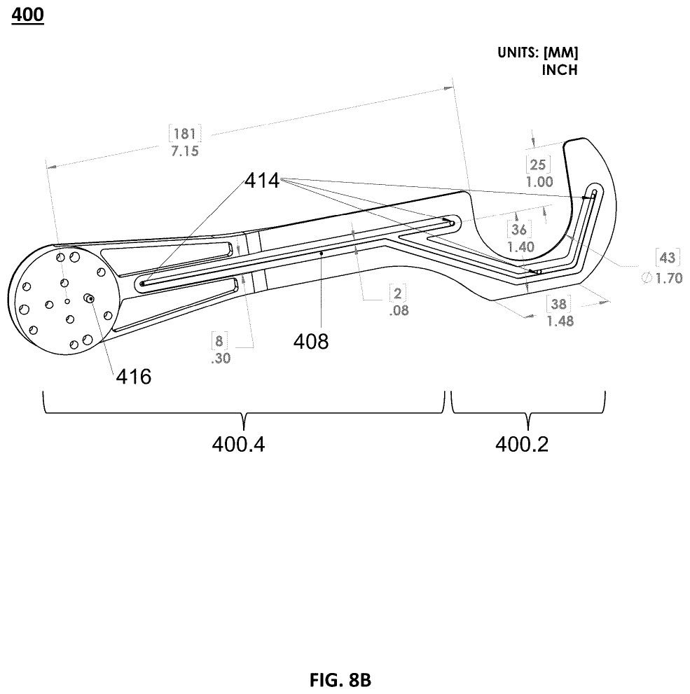

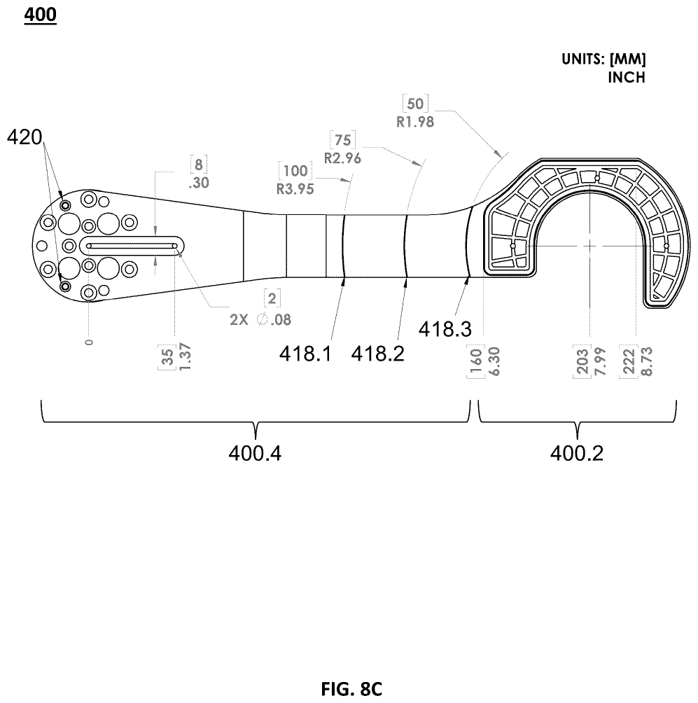

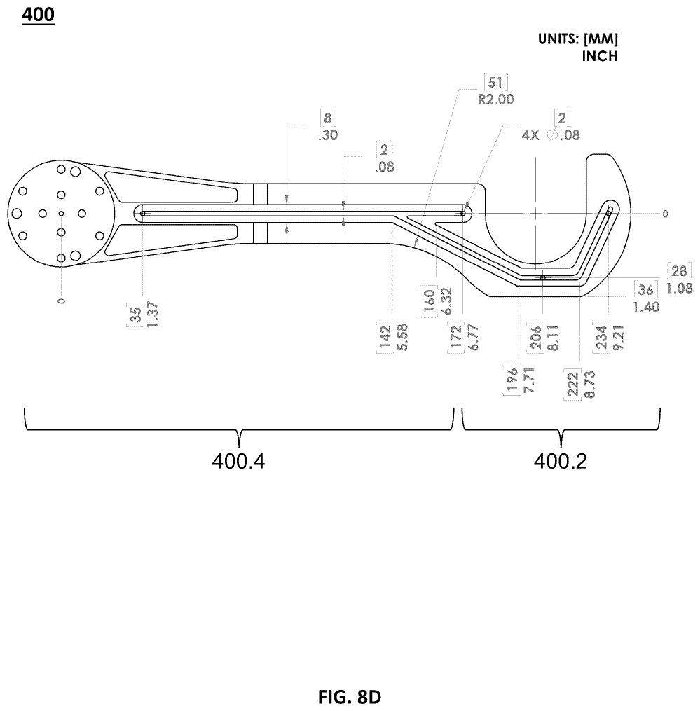

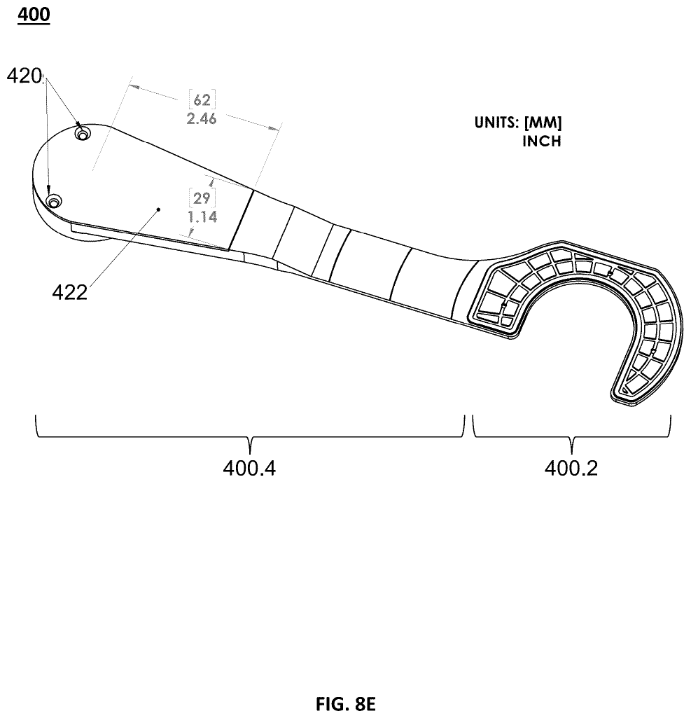

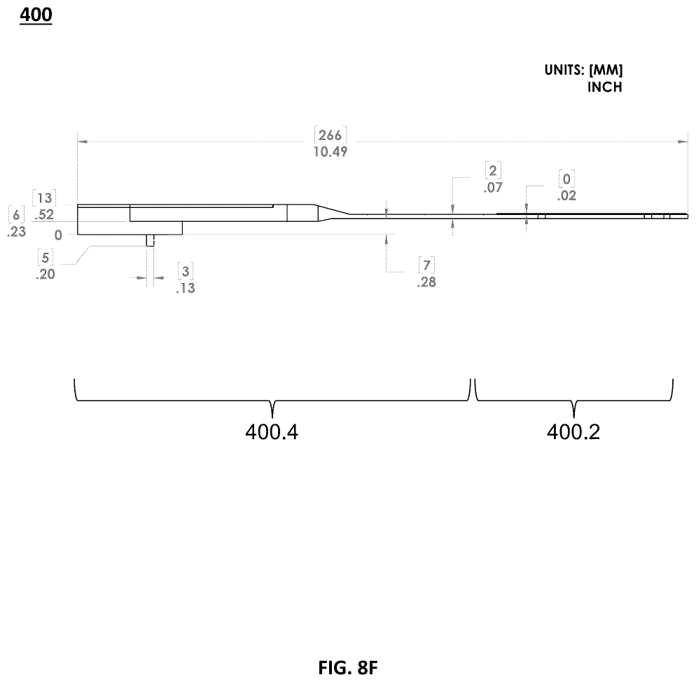

FIGS. 8A-8F illustrate the end effector 400.2 and the end effector arm 400.4 of the end effector module 400 of the apparatus 100 in different configurations or views for handling or positioning a wafer. FIG. 8A illustrates a perspective view of the end effector 400.2 and the end effector arm 400.4, which can be configured to include: a main body 402 of the end effector arm 400.4 for structural support and for transferring vacuum pressure; a top vacuum groove 406 for transferring vacuum pressure from a vacuum supply ring assembly 716 to a bottom vacuum groove 408; one or more mounting holes 410 for coupling the end effector arm 400.4 to the stepper motor 432 (e.g., a rotary motor) of the end effector module 400; and one or more mounting holes 412 for coupling the end effector module 400 to the vacuum supply ring assembly 716. FIG. 8B illustrates another perspective view of the end effector 400.2 and the end effector arm 400.4, which can be configured to include: a bottom vacuum groove 408 for transferring vacuum pressure from the top vacuum groove 406 to one or more vacuum holes 414; the one or more vacuum holes 414 for transferring the vacuum pressure from the bottom vacuum groove 408 to the top side of the end effector 400.2 and the end effector arm 400.4 for handling a wafer; and one or more pins 416 (e.g., dowel pins) for indexing the end effector arm 400.4 to the vacuum supply ring assembly 716. FIG. 8C illustrates a plan view (top view) of the end effector 400.2 and the end effector arm 400.4, which can be configured to include: an indexing scribed line 418.1 for placement of a 100 millimeter (mm) wafer; an indexing scribed line 418.2 for placement of a 150 mm wafer; an indexing scribed line 418.3 for placement of a 200 mm wafer; and one or more mounting holes 420 for coupling a top cover 422 to the main body 402. FIG. 8D illustrates another plan view (bottom view) of the end effector 400.2 and the end effector arm 400.4. FIG. 8E illustrates another perspective view of the end effector 400.2 and the end effector arm 400.4, which can be configured to include: the top cover 422 for protecting described components of the end effector module 400; and the one or more mounting holes 420 for coupling the top cover 422 to the main body 402. FIG. 8F illustrates another plan view (side view) of the end effector 4002. and the end effector arm 400.4

### Pluck Module

The apparatus 100 can be configured with a pluck module 200. In some embodiments, the pluck module 200 comprises a pluck 206 configured to releasably hold the wafer using a pattern of vacuum grooves 284 operatively coupled to a vacuum source. In some embodiments, the pluck module 200 comprises a first motor 202 and shaft 260 coupled thereto configured to rotate the pluck 206 around an axis normal to the stage module 500. In some embodiments, the pluck module 200 comprises a second motor 228 and shaft 230 coupled thereto configured to translate the pluck 206 along the axis normal to the stage module 500. In some embodiments, the pluck module 200 comprises one or more limit switches 212 configured to limit movement of the pluck 206 to (i) a predetermined upper limit, (ii) a predetermined lower limit, or (iii) a predetermined intermediate position. In some embodiments, the pluck module 200 comprises a brake configured to stop the translation of the pluck 206 along the axis normal to the stage module 500. In some embodiments, the pluck module 200 comprises a controller module 250 configured to collectively operate the pluck 206, the first motor 202, the second motor 228, the one or more limit switches 212, the brake, the vacuum source, or any combination thereof. In some embodiments, the pluck module 200 is configured to be interchangeable with another pluck module 200 of the same type.

In some embodiments, a vacuum module 700 is configured to control the vacuum source to adjust a vacuum pressure to the pattern of vacuum grooves 284 based at least on a size of the wafer. In some embodiments, the pluck 206 is configured to (i) operate inside a central portion of the chuck module 300, (ii) extend beyond a plane of the chuck module 300, (iii) retract to or below the plane of the chuck module 300, or (iv) any combination of (i)-(iii). In some embodiments, the pluck 206 is configured to rotate the wafer proximate to the alignment module 600 for obtaining an alignment of the wafer. In some embodiments, the pluck 206 is configured to: translate along a central vertical axis of the chuck module 300; and rotate around the central vertical axis of the chuck module 300. In some embodiments, the pluck 206 is concentrically aligned along a central vertical axis of the chuck module 300.

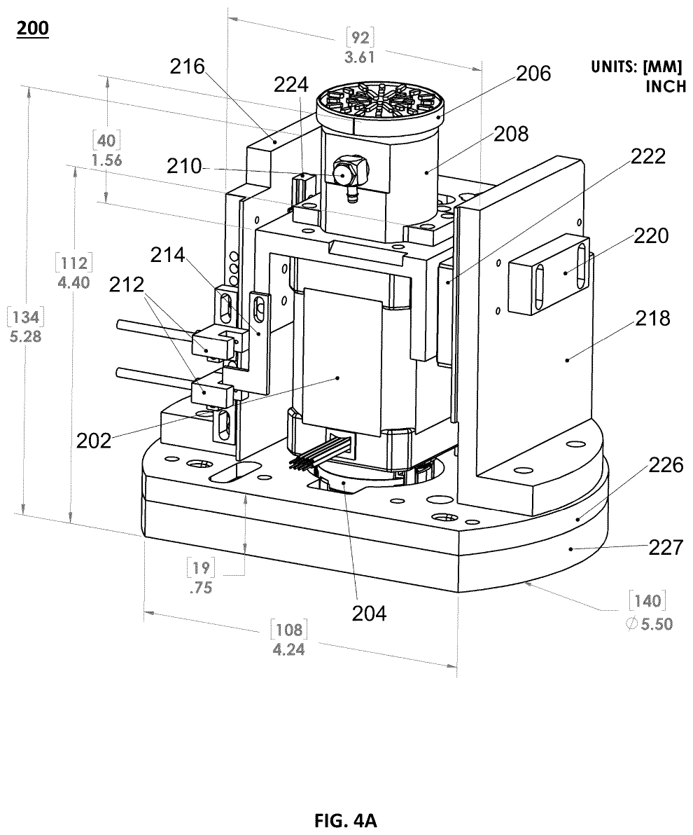

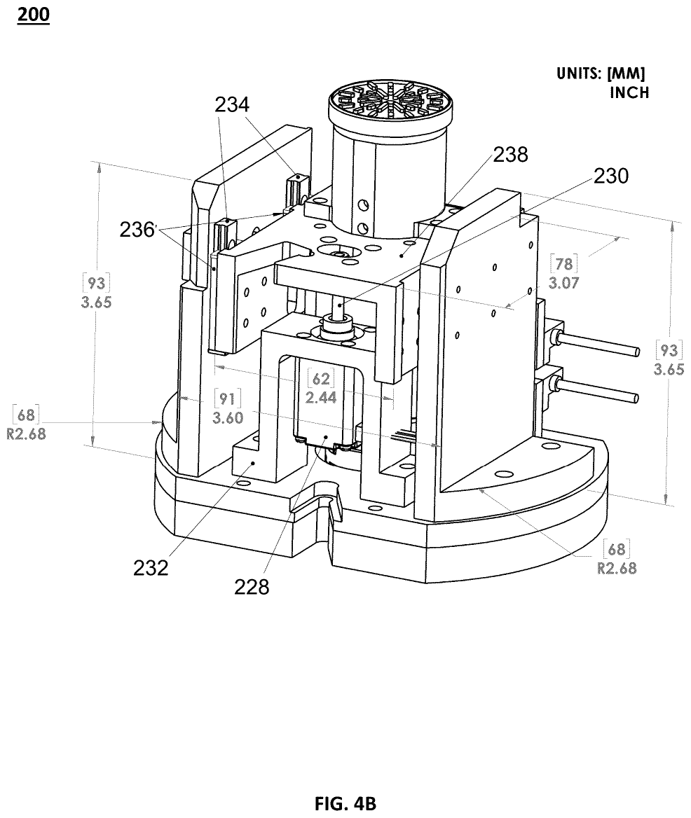

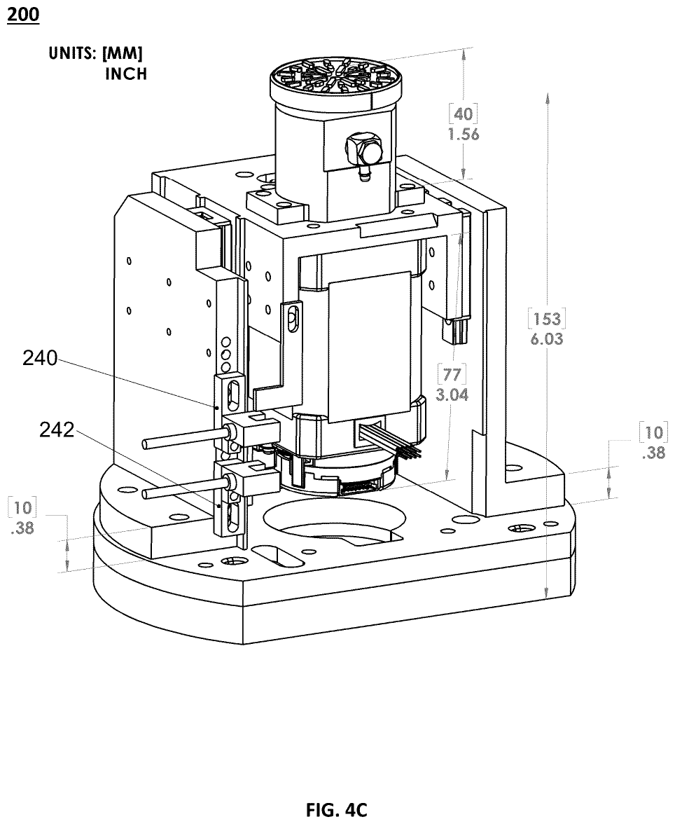

FIGS. 4A-4C illustrate the pluck module 200 of the apparatus 100 in different configurations or views for handling or positioning a wafer. FIG. 4A illustrates a perspective view of the pluck module 200 in its lowest position, which can be configured to include: a rotary motor 202 for rotating the pluck 206; an encoder 204 for determining a rotation of the rotary motor 202; one or more limit switches 212 (e.g., 2 switches) for limiting a vertical movement (e.g., Z movement) of the pluck 206; one or more limit switch flags 214 for determining a vertical movement or position of the pluck 206; one or more mounts 216 (left) and 218 (right) for mounting the pluck module 200 to the base top 226 and mechanically coupled to linear slide rails 224 and 234; one or more hard stops 220 (e.g., 1 hard stop) for limiting a vertical movement (e.g., Z movement) of the pluck 206; a linear slide carriage 236 operatively coupled to the linear slide rails 234 and mechanically coupled to the slide mount 238 for directing a vertical movement (e.g., Z movement) of the pluck 206; a linear slide carriage 222 operatively coupled to the linear slide rail 224 and mechanically coupled to the slide mount 238 for directing a vertical movement (e.g., Z movement) of the pluck 206; a base top 226 for mounting the pluck module 200 to the base bottom 227; a base bottom 227 for mounting the pluck module 200 to the apparatus 100; a vacuum supply housing 208 to operatively contain vacuum pressure within the pluck module 200 received from the vacuum module 700; and a vacuum fitting 210 to operatively transmit vacuum pressure to the pluck module 200 from the vacuum module 700. FIG. 4B illustrates another perspective view of the pluck module 200 in its lowest position, which can be configured to include: a Z motor 228 for moving the pluck 206 along a vertical direction (e.g., Z movement); a Z motor shaft 230 mechanically coupled to the Z motor 228 for transferring a torque of the Z motor 228 to the slide mount 238; a Z motor mount 232 for mounting the Z motor 228 to the base top 226; the linear side rails 224 and 234 described herein; the slide carriages 222 and 236 described herein; and the slide mount 238 described herein. FIG. 4C illustrates another perspective view of the pluck module 200 in its highest position, which can be configured to include an upper limit mount 240 and a lower limit 242 for mounting the limit switches 212.

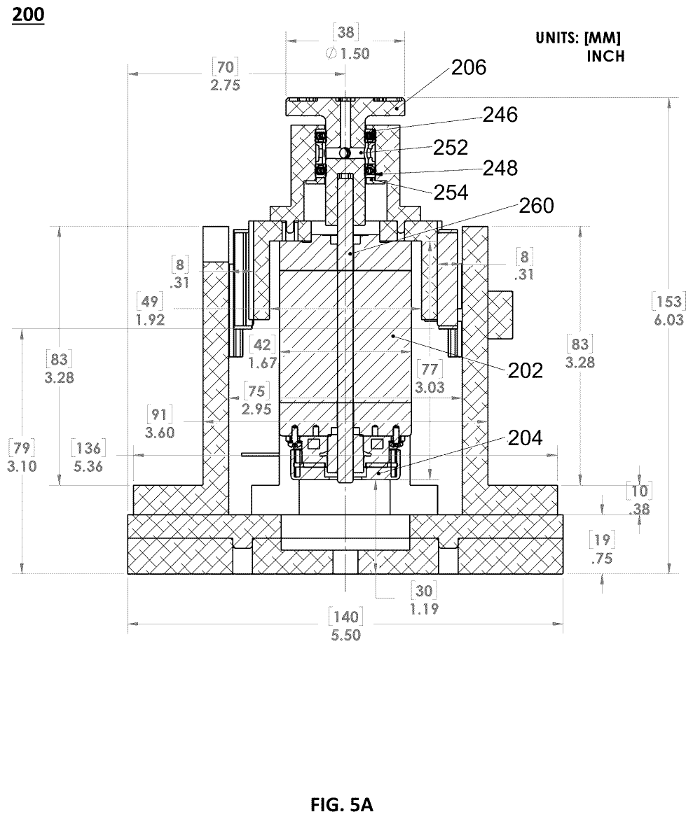

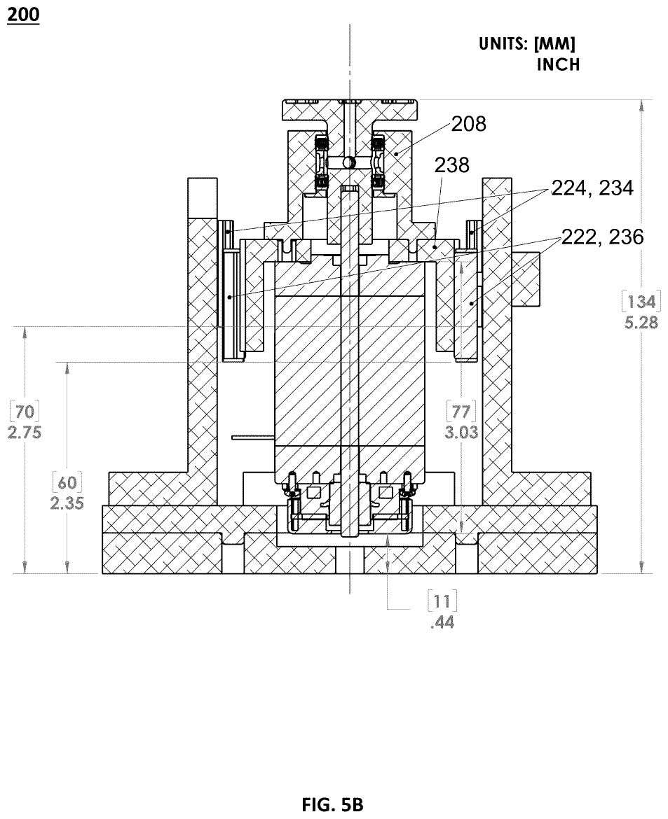

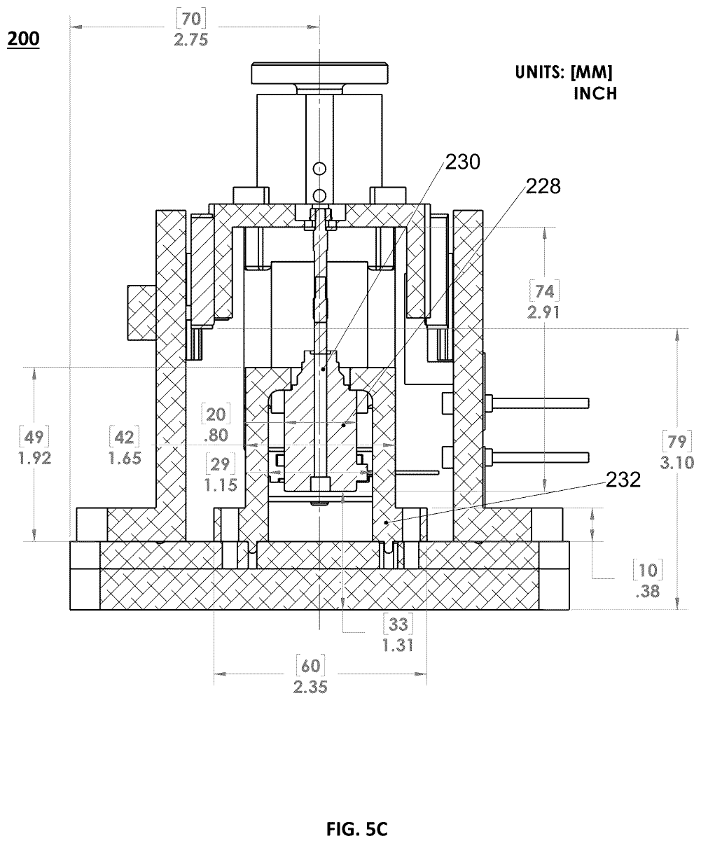

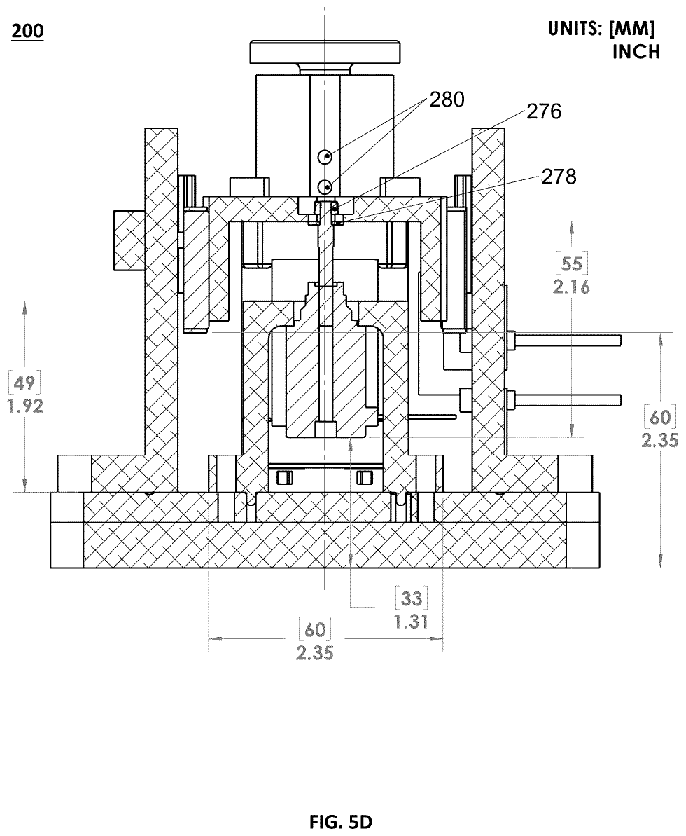

FIGS. 5A-5D illustrate the pluck module 200 of the apparatus 100 in different configurations or views for handling or positioning a wafer. FIG. 5A illustrates a cross-sectional view of the pluck module 200 in its highest position from the side of the rotary motor 202, which can be configured to include: the pluck 206 described herein; an upper vacuum seal 246 configured to seal a vacuum pressure of the pluck 206; a lower vacuum seal 248 configured to seal a vacuum pressure of the pluck 206; a vacuum distributor 252 configured to distribute the vacuum pressure to the pattern of grooves 284 of the pluck 206; a vacuum supply housing cover 254 for the pluck 206; the rotary motor 202 describe herein; the rotary motor encoder 204 described herein; and a rotary motor shaft 260, which mechanically couples the rotary motor 202 to the pluck 206 and is configured to transmit a torque from the rotary motor 202 to the pluck 206.

FIG. 5B illustrates another cross-sectional view of the pluck module 200 in its lowest position from the side of the rotary motor 202, which can be configured to include: the vacuum supply housing 208 described herein; the slide mount 238 described herein; the linear slide carriages 222 and 236 described herein; and the linear slide rails 224 and 234 described herein. FIG. 5C illustrates another cross-sectional view of the pluck module 200 in its highest position from the side of the Z motor 228, which can be configured to include: the Z motor 228 described herein; the Z motor shaft 230 described herein; and the Z motor mount 232 described herein. FIG. 5D illustrates another cross-sectional view of the pluck module 200 in its lowest position from the side of the Z motor 228, which can be configured to include: a Z motor shaft mounting nut 276 and a Z motor shaft support washer 278 collectively configured to secure the slide mount 238 to the Z motor shaft 230; and one or more pluck locking set screws 280 collectively configured to secure the pluck 200 to the rotary motor shaft 260.

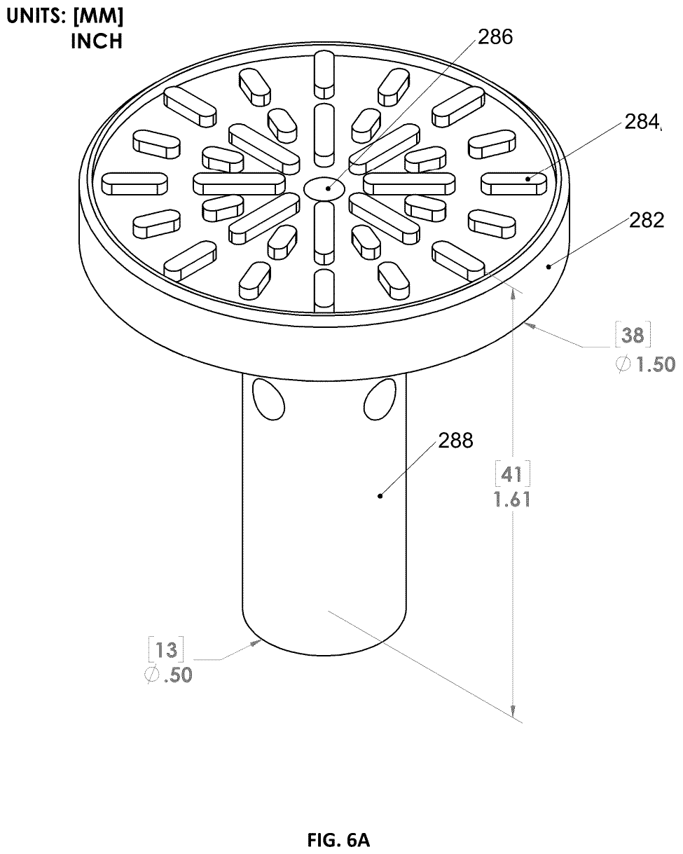

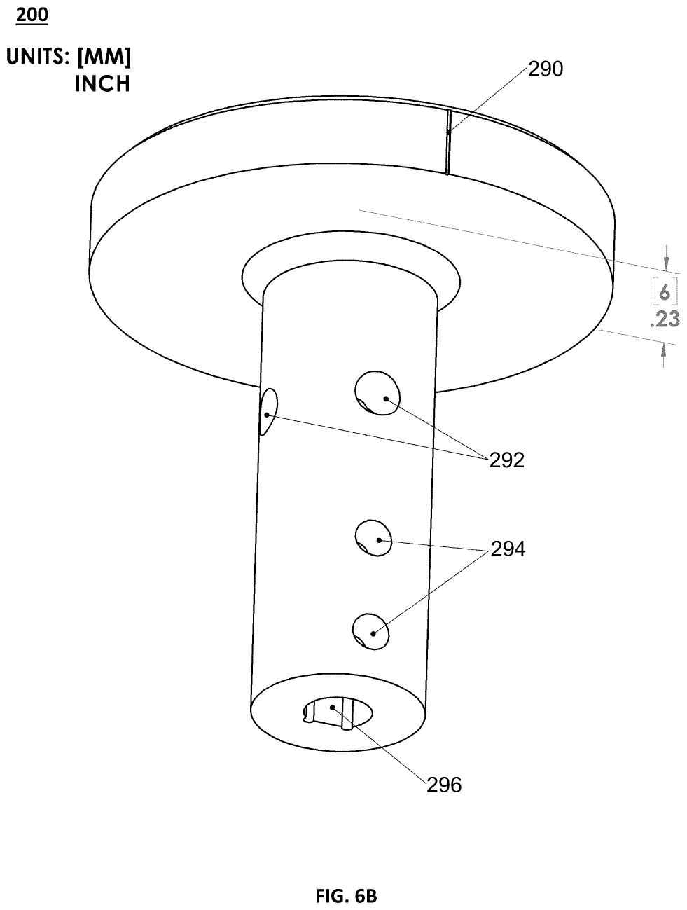

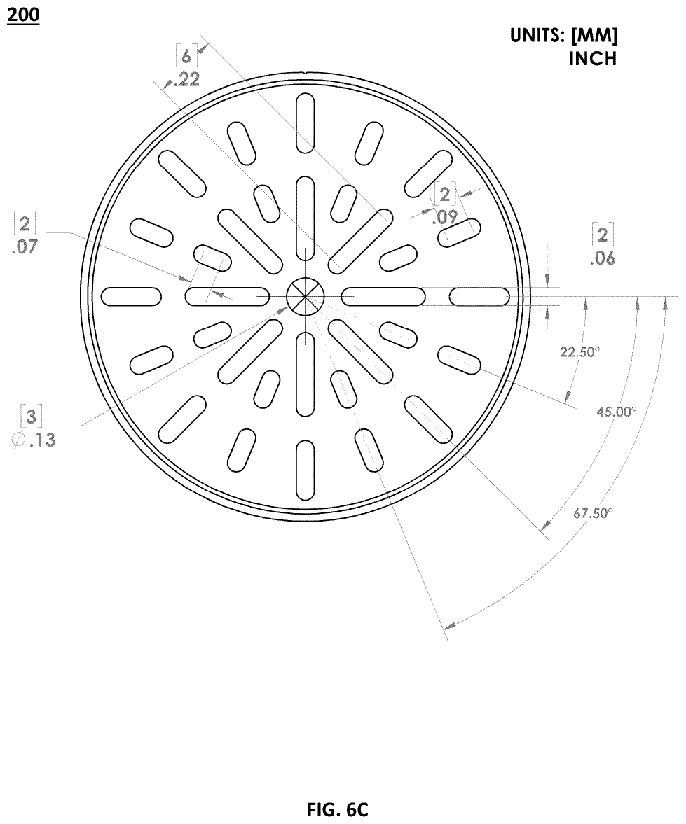

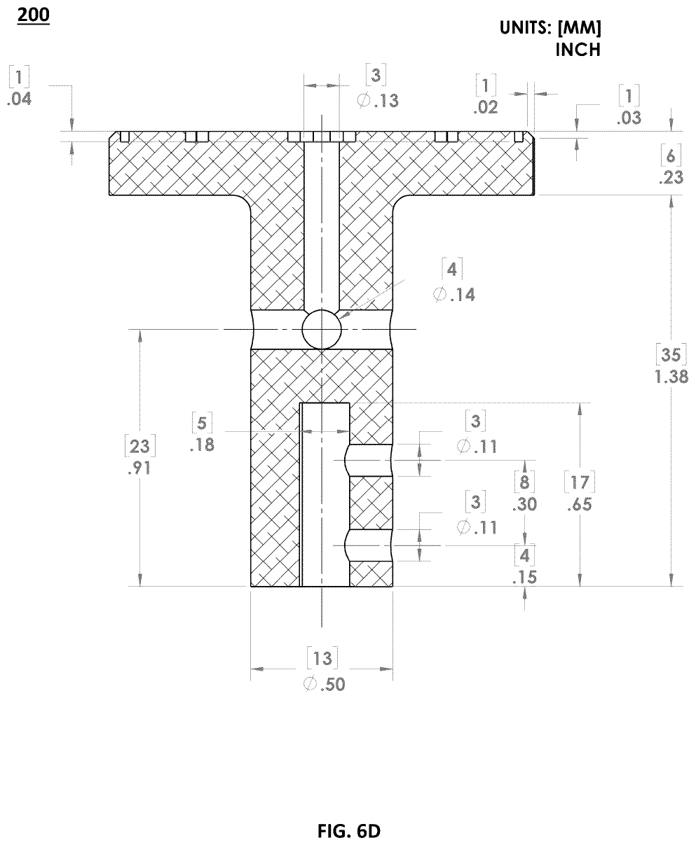

FIGS. 6A-6D illustrate the pluck 206 of the pluck module 200 of the apparatus 100 in different configurations or views for handling or positioning a wafer. FIG. 6A illustrates a perspective view of the pluck 206, which can be configured to include: a pluck main body 282 configured to support or contain the pattern of grooves 284; the pattern of vacuum grooves 284 configured to releasably hold a wafer through operation of the vacuum module 700; a pluck vacuum supply hole 286 configured to transmit the vacuum pressure to the pattern of grooves 284 through operation of the vacuum module 700; and a pluck stem 288 configured to operatively couple the pluck 200 to the rotary motor shaft 260 of the rotary motor 202 describe herein. FIG. 6B illustrates another perspective view of the pluck 206, which can be configured to include: one or more pluck alignment marks 290; one or more vacuum distribution holes 292; one or more pluck locking set screws 280 described herein, and a rotary motor mounting hole 296 configured to receive the rotary motor shaft 260 into the pluck stem 288 of the pluck 206. FIG. 6C illustrates a plan view (top view) of the pluck 206, which can be configured to include the pattern of vacuum grooves 284. FIG. 6D illustrates a cross-sectional view of the pluck 206, which can be sized according to user requirements.

### Alignment Module

The apparatus 100 can be configured with an alignment module 600. In some embodiments, the alignment module 600 comprises an optical sensor configured to detect the alignment feature. In some embodiments, the alignment module 600 comprises a controller module configured to use at least the alignment feature for determining the virtual center of the wafer. In some embodiments, at least the virtual center of the wafer is used to align the wafer to the inspection station. In some embodiments, the optical sensor comprises a photoelectric sensor. In some embodiments, the alignment module 600 is configured to be interchangeable with another alignment module 600 of the same type.

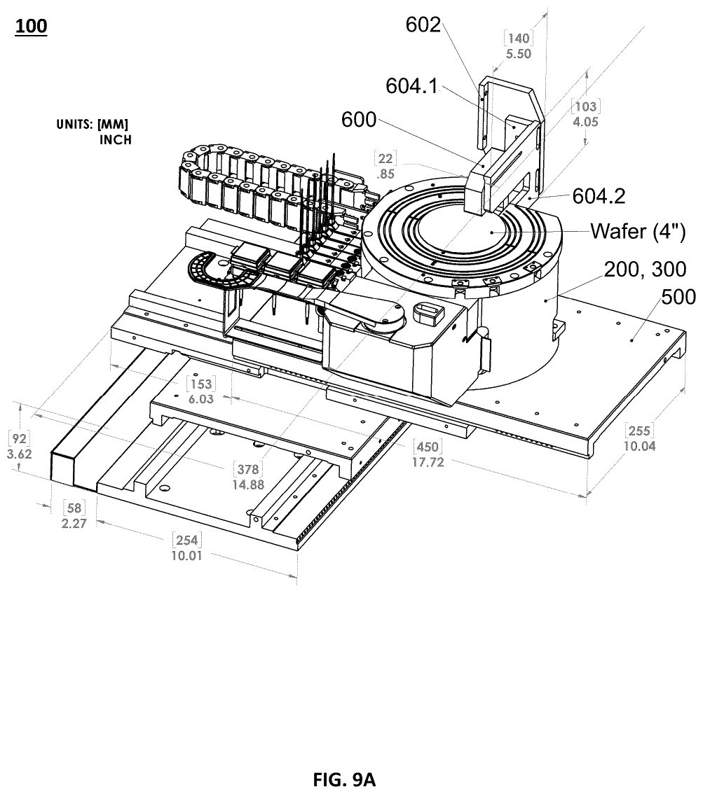

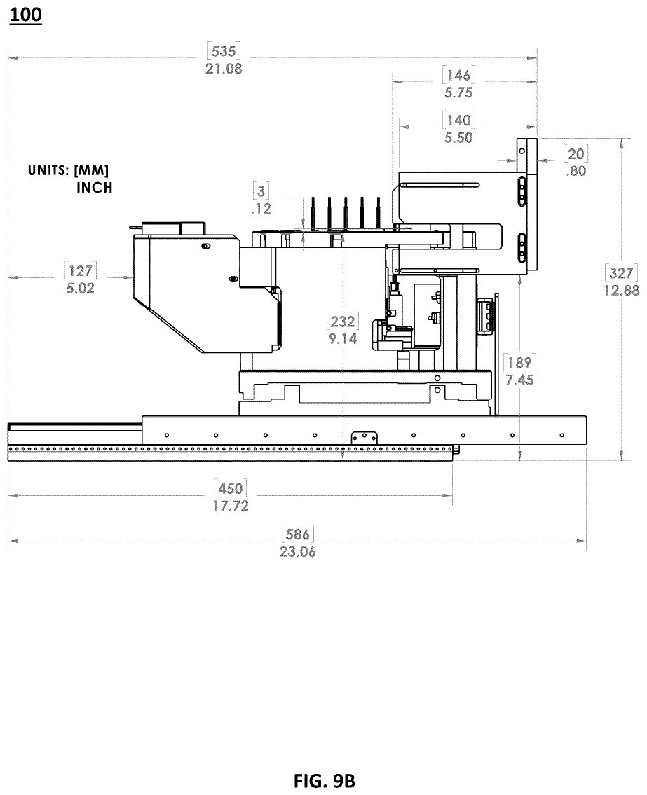

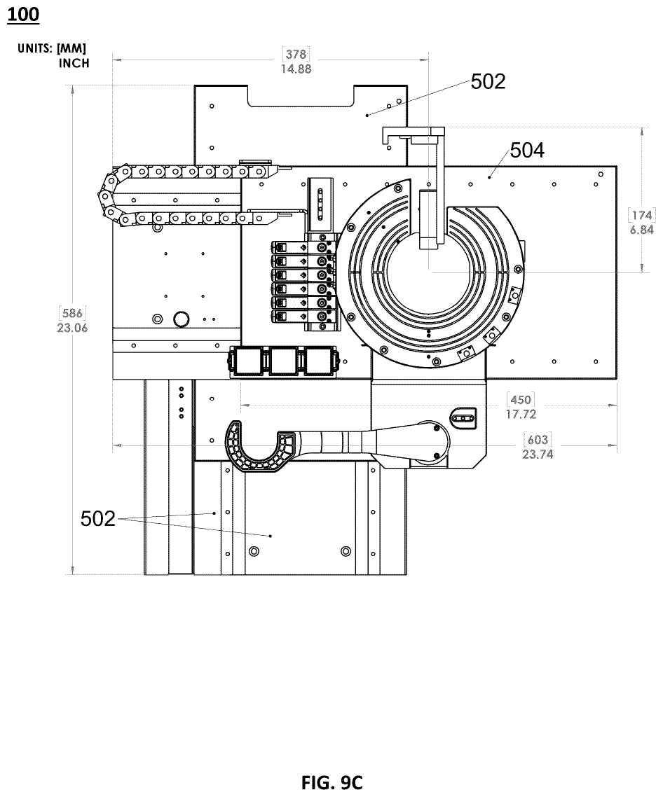

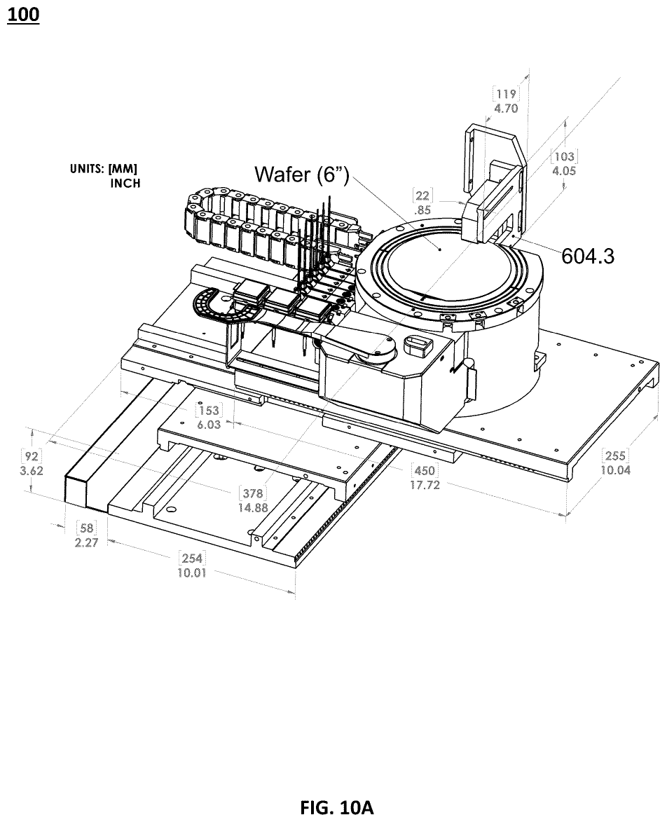

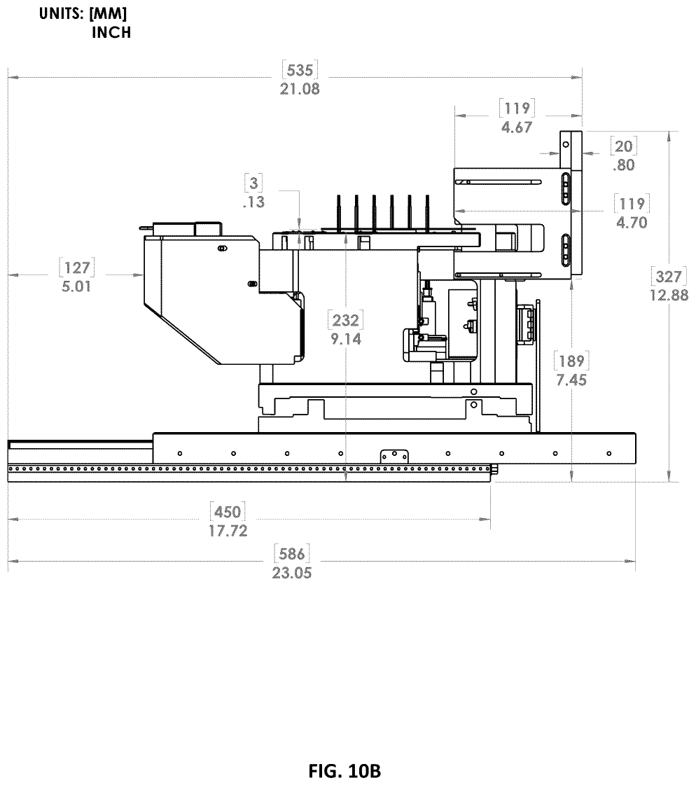

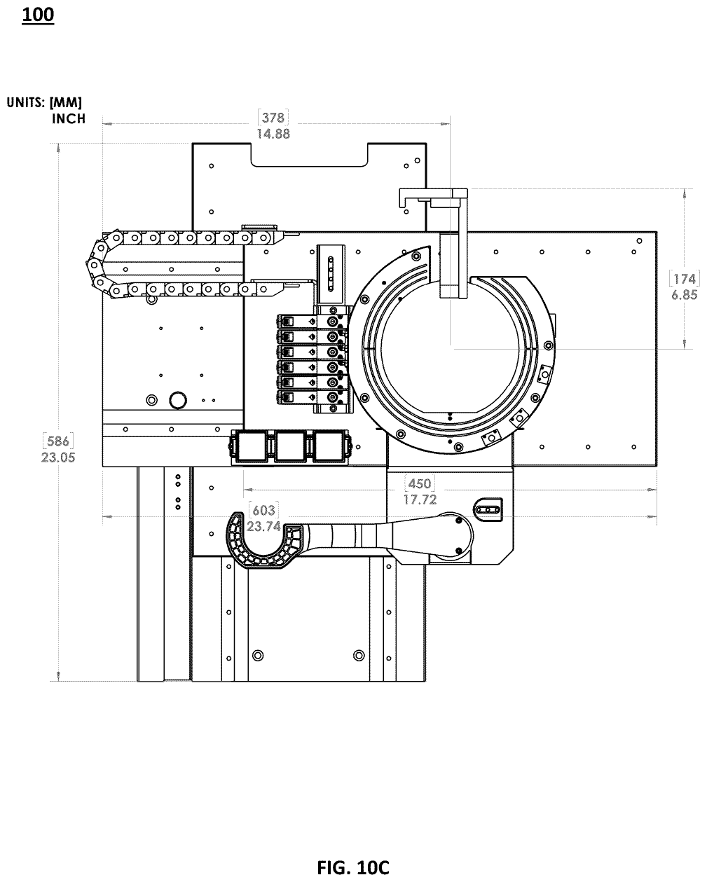

FIGS. 9A-9C illustrate the alignment module 600 of the apparatus 100 for handling or positioning a wafer, e.g., a 100 millimeter (mm) wafer. FIG. 9A illustrates a perspective view of the alignment module 600, which can be configured to include: a main mount 602 for mounting the alignment module 600 to the apparatus 100 or the inspection station; a side adjustment mount 604.1 for mounting the alignment module 600 to the main mount 602 or adjusting the alignment module 600 for handling a 100 millimeter (mm) wafer; and a side adjustment mount 604.2 for mounting the alignment module 600 to the main mount 602 or adjusting the alignment module 600 for handling a 100 millimeter (mm) wafer. FIG. 9B illustrates a plan view (side view) of the alignment module 600 for handling or positioning a 100 mm wafer. FIG. 9C illustrates another plan view (top view) of the alignment module 600 for handling or positioning a 100 mm wafer, which can be aligned to the stage module 500, e.g., the bottom stage axis 502 and the top stage axis 504 of the stage module 500. FIGS. 10A-10C illustrate the alignment module 600 of the apparatus 100 for handling or positioning a wafer, e.g., a 150 millimeter (mm) wafer. FIG. 10A illustrates a perspective view of the alignment module 600, which can be configured to include: a main mount 602 for mounting the alignment module 600 to the apparatus 100 or the inspection station; a side adjustment mount 604.1 for mounting the alignment module 600 to the main mount 602 or adjusting the alignment module 600 for handling a 150 millimeter (mm) wafer; and a side adjustment mount 604.3 for mounting the alignment module 600 to the main mount 602 or adjusting the alignment module 600 for handling a 150 millimeter (mm) wafer. FIG. 10B illustrates a plan view (side view) of the alignment module 600 for handling or positioning a 150 mm wafer. FIG. 10C illustrates another plan view (top view) of the alignment module 600 for handling or positioning a 150 mm wafer, which can be aligned to the stage module 500, e.g., the bottom stage axis 502 and the top stage axis 504 of the stage module 500.

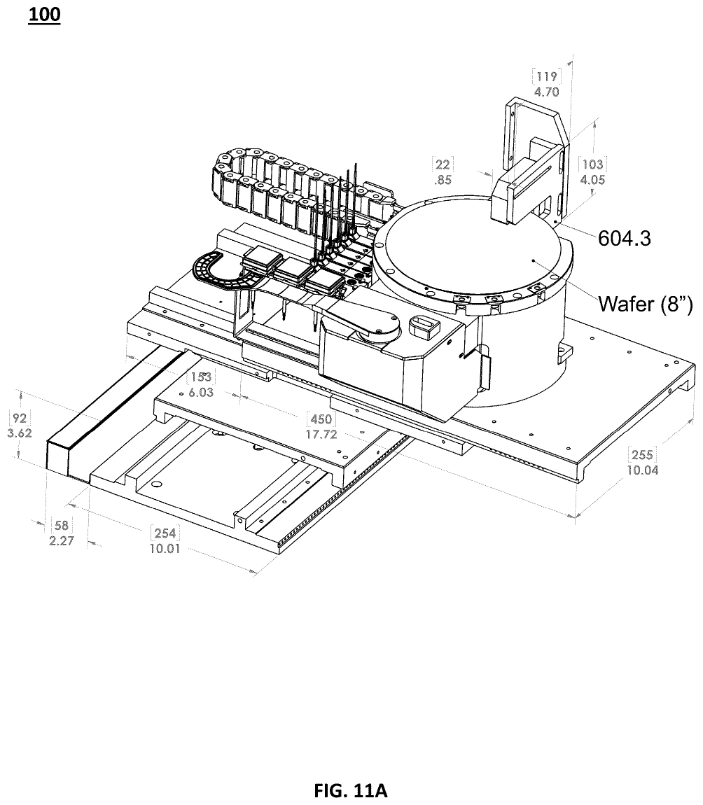

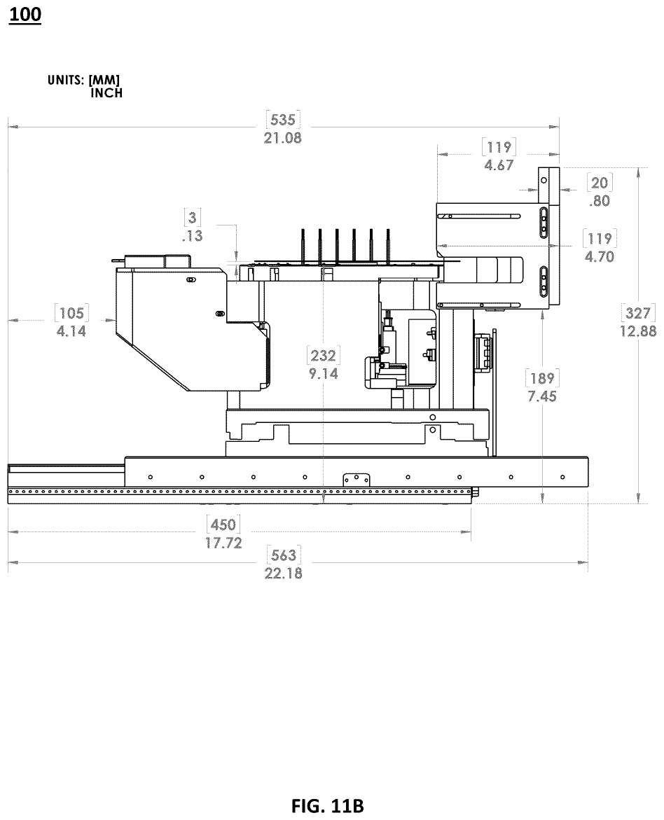

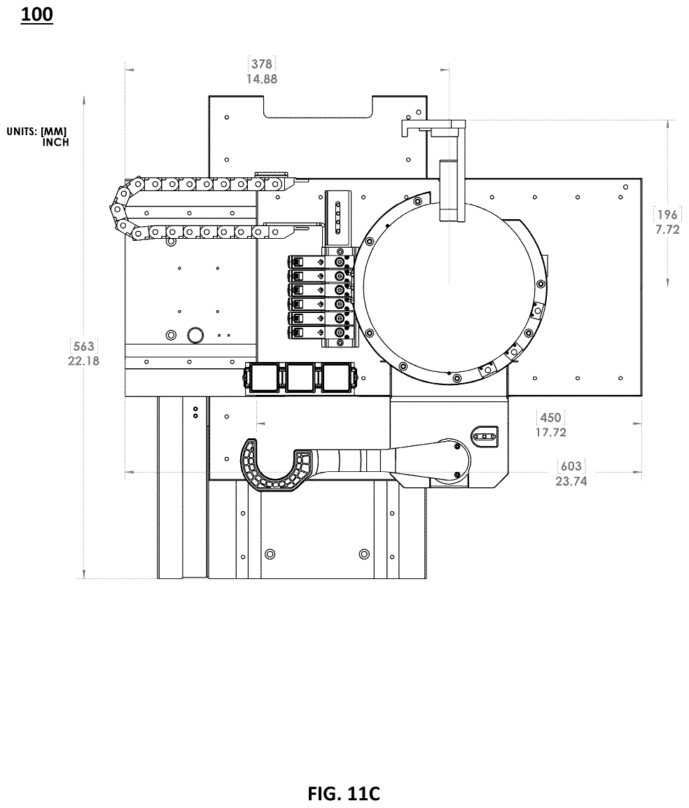

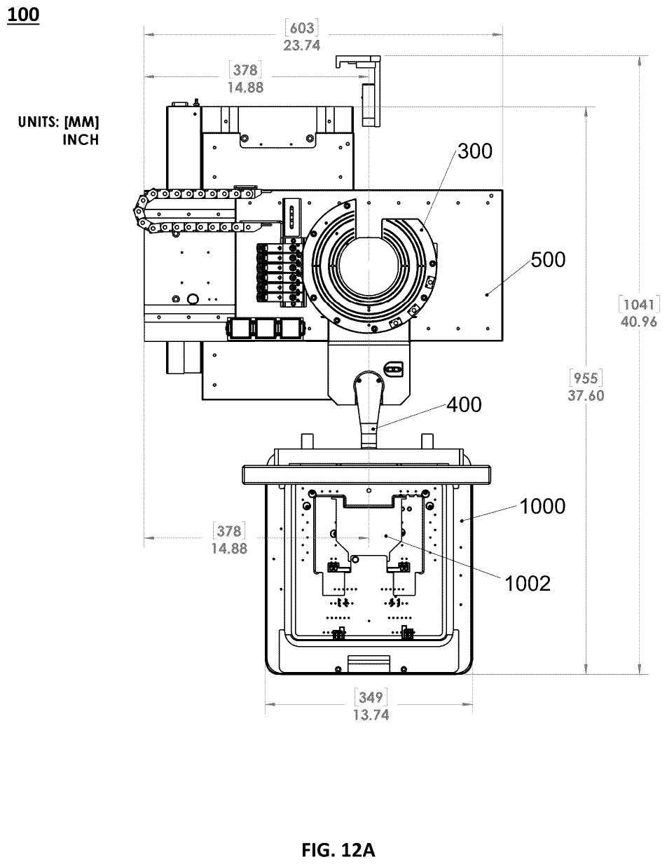

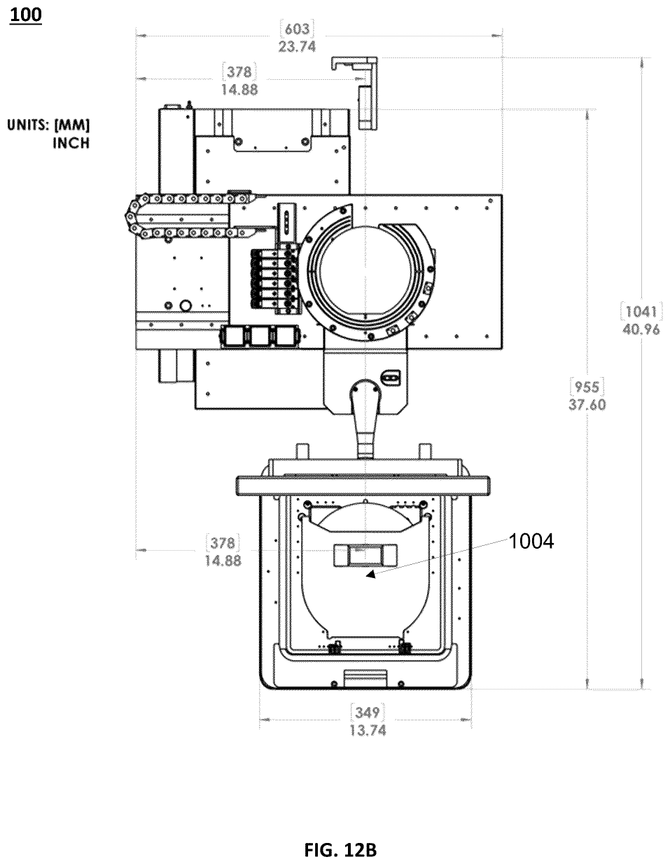

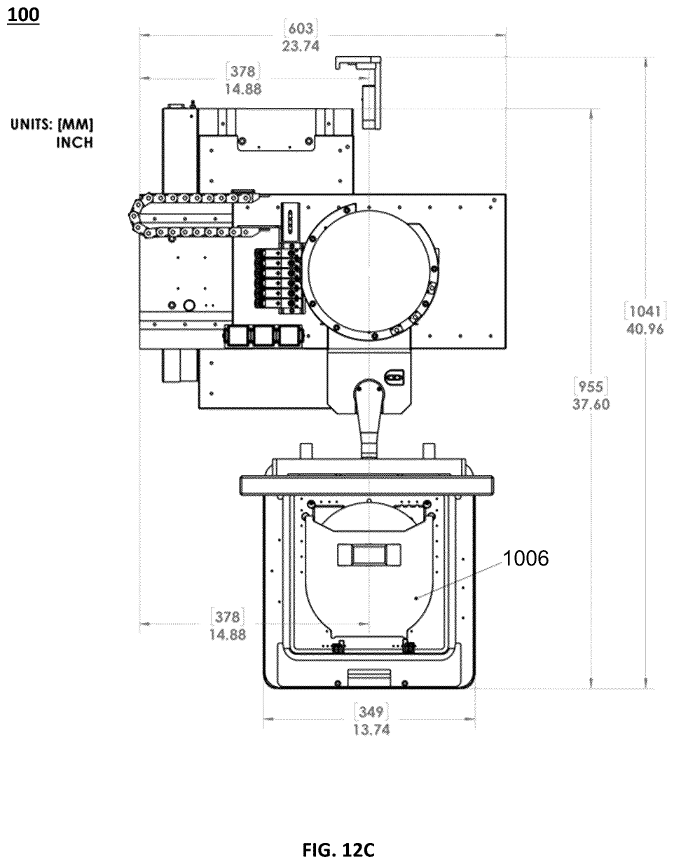

FIGS. 11A-11C illustrate the alignment module 600 of the apparatus 100 for handling or positioning a wafer, e.g., a 200 millimeter (mm) wafer. FIG. 11A illustrates a perspective view of the alignment module 600, which can be configured to include: a main mount 602 for mounting the alignment module 600 to the apparatus 100 or the inspection station; a side adjustment mount 604.1 for mounting the alignment module 600 to the main mount 602 or adjusting the alignment module 600 for handling a 200 millimeter (mm) wafer; and a side adjustment mount 604.3 for mounting the alignment module 600 to the main mount 602 or adjusting the alignment module 600 for handling a 200 millimeter (mm) wafer. FIG. 11B illustrates a plan view (side view) of the alignment module 600 for handling or positioning a 200 mm wafer. FIG. 11C illustrates another plan view (top view) of the alignment module 600 for handling or positioning a 200 mm wafer, which can be aligned to the stage module 500, e.g., the bottom stage axis 502 and the top stage axis 504 of the stage module 500.

### Chuck Module

The apparatus 100 can be configured with a chuck module 300. In some embodiments, the chuck module 300 comprises a chuck 302 configured to releasably hold the wafer using a pattern of independently addressable vacuum grooves (316.1, 316.2, and 316.3) operatively coupled to a vacuum source of the vacuum module 700. In some embodiments, the chuck module 300 comprises a controller module 350 configured to collectively operate the chuck 302 and the vacuum source. In some embodiments, the chuck module 300 is configured to be interchangeable with another chuck module 300 of the same type.

In some embodiments, a vacuum module 700 is configured to control the vacuum source to adjust a vacuum pressure to each pattern of the pattern of independently addressable vacuum grooves (316.1, 316.2, and 316.3) based at least on a size of the wafer. In some embodiments, a diameter of the chuck 302 is equal to or greater than a diameter of the wafer. In some embodiments, the chuck 302 is (i) rotationally fixed relative to a vertical axis of the stage module 500, (ii) translationally fixed relative to a plane of the stage module 500, or both (i) and (ii).

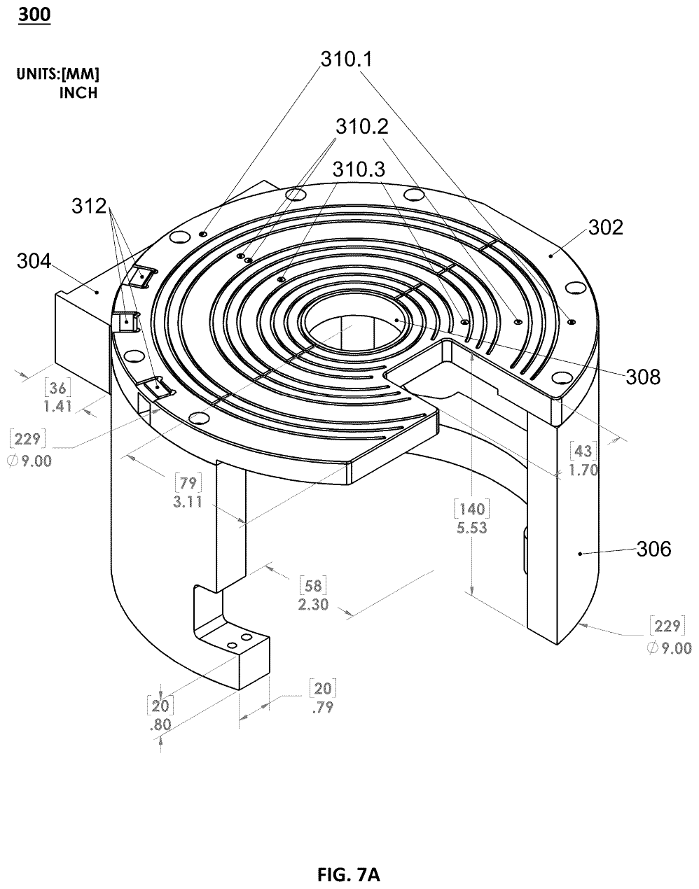

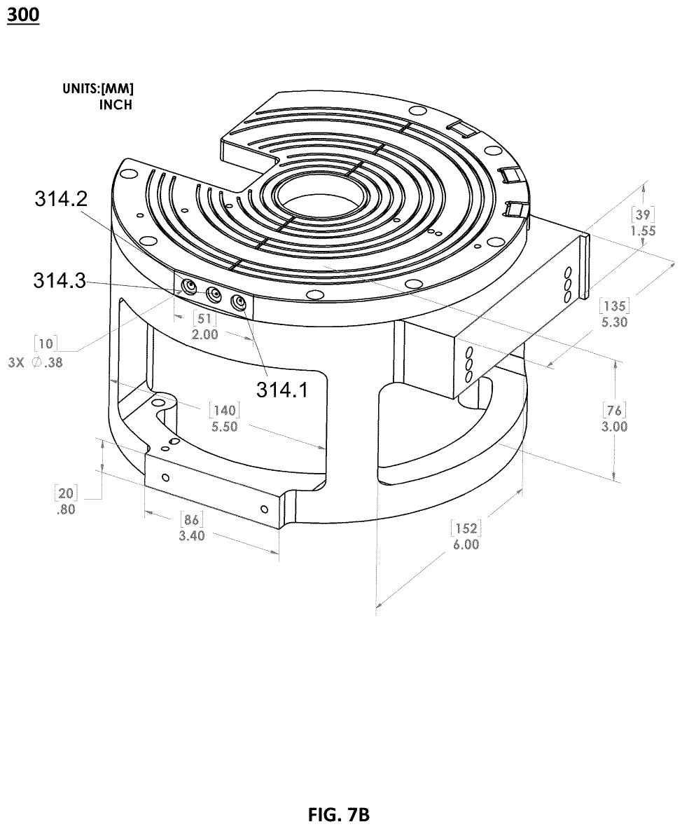

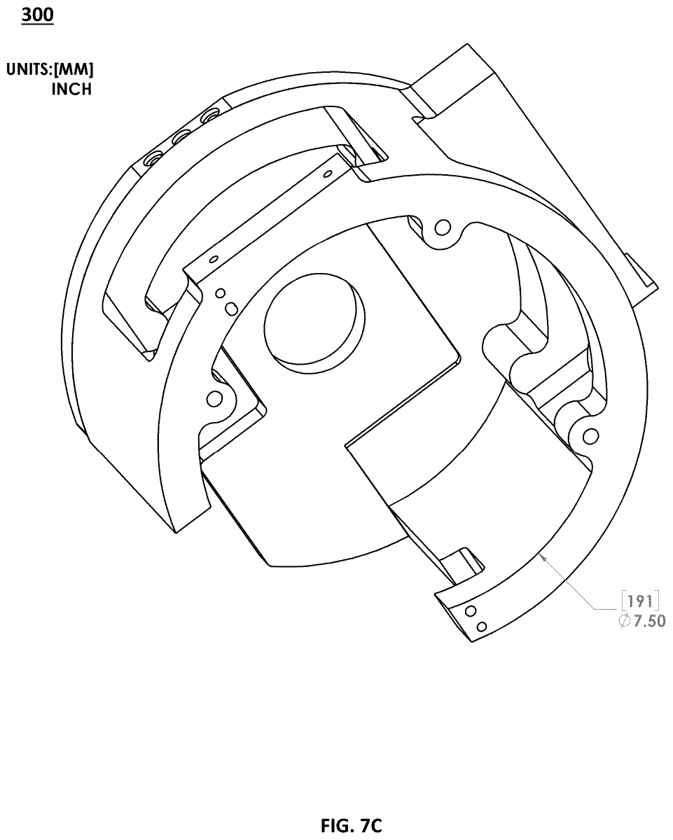

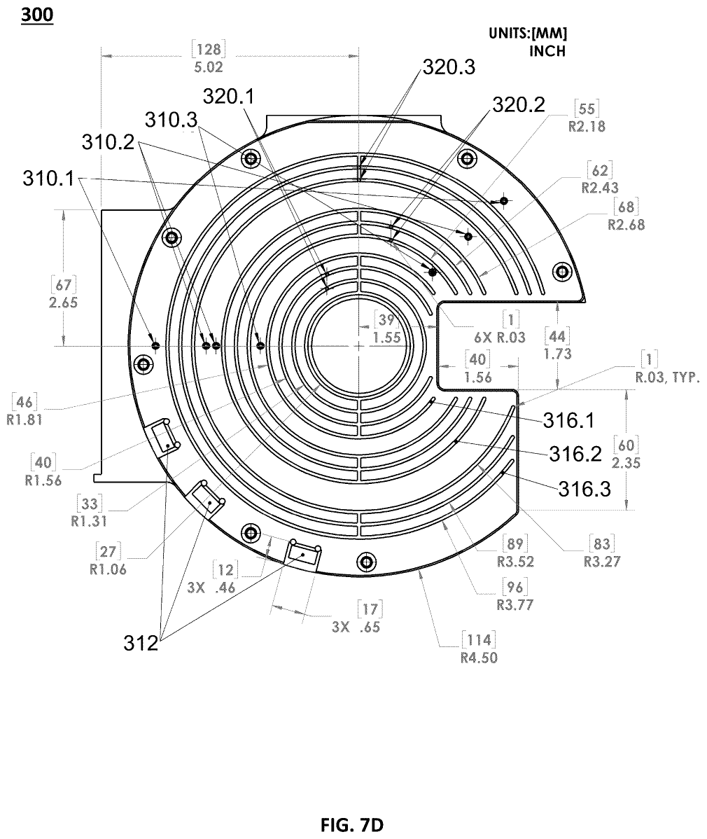

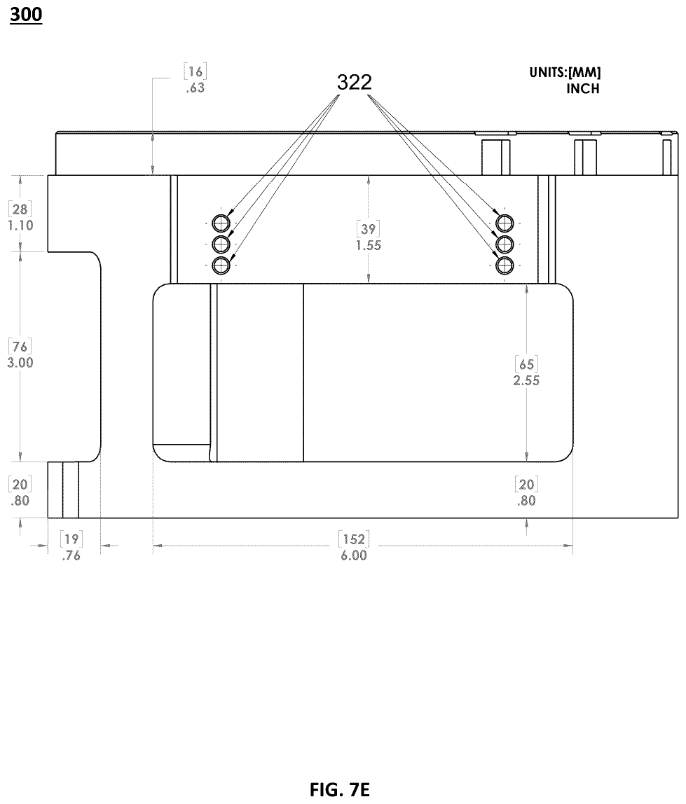

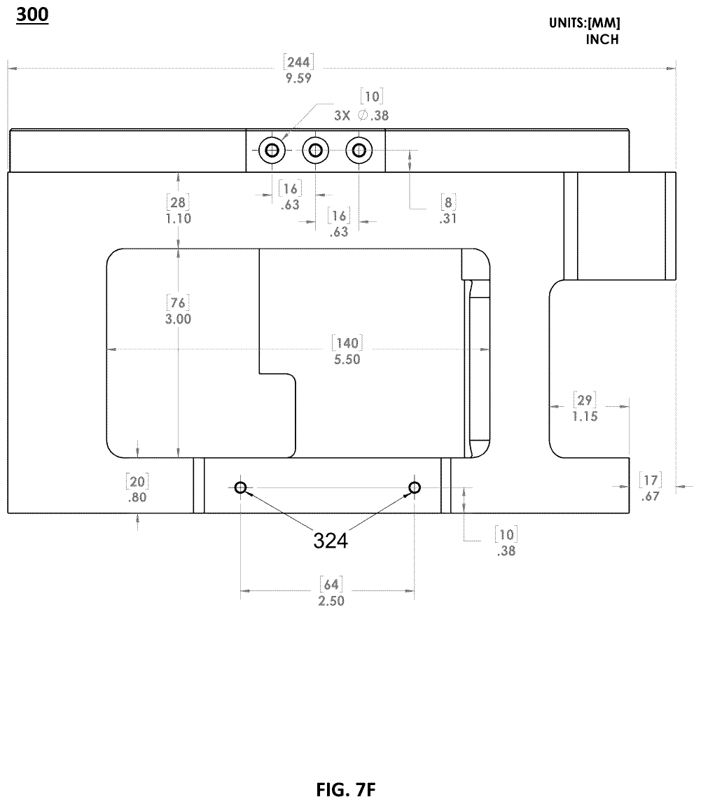

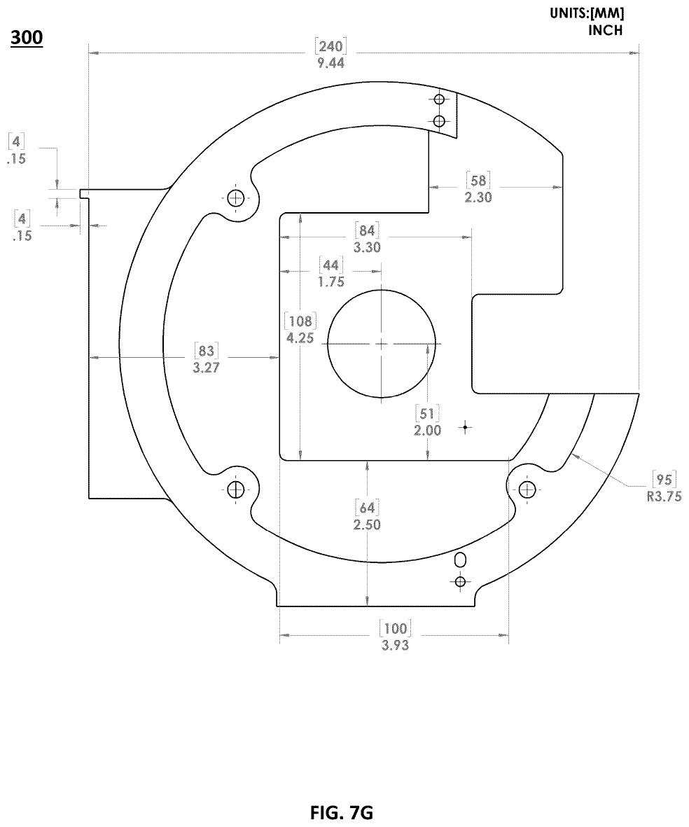

FIGS. 7A-7G illustrate the chuck module 300 of the apparatus 100 in different configurations or views for handling or positioning a wafer. FIG. 7A illustrates a perspective view of the chuck module 300, which can be configured to include: a top surface 302 for supporting a water and containing the independently addressable vacuum grooves (316.1, 316.2, and 316.3); an assembly and mount 304 to couple the end effector module 400 and the rotary motor 432 to the chuck module 300; a chuck support 306 for coupling the top surface 302 to stage module 500; a central opening 308 for operation of the pluck 206 of the pluck module 200; indexing pin mounting holes for positioning wafers of different sizes, e.g., 310.1 for a 200 millimeter (mm) wafer, 310.2 for a 150 mm wafer, and 310.3 for a 100 mm wafer; and baseline pads mounts 312 for securing a pad (e.g., a silicon pad) that can be in a form of a 100 mm wafer, a 150 mm wafer, or a 200 mm wafer. In some cases, the pad may be used for one or more reference measurements. FIG. 7B illustrates another perspective view of the chuck module 300, which can be configured to include: a vacuum fitting hole 314.1 for providing vacuum pressure to independently addressable vacuum groove 316.1 for handling a 100 millimeter (mm) wafer; a vacuum fitting hole 314.2 for providing vacuum pressure to independently addressable vacuum groove 316.2 for handling a 150 millimeter (mm) wafer; and a vacuum fitting hole 314.3 for providing vacuum pressure to independently addressable vacuum groove 316.3 for handling a 200 millimeter (mm) wafer. FIG. 7C illustrates another perspective view of the chuck module 300 from a bottom view of the chuck module 300. FIG. 7D illustrates a plan view (top view) of the chuck module 300, which can be configured to include: independently addressable vacuum groove 316.1 for a 100 millimeter (mm) herein; independently addressable vacuum groove 316.2 for a 150 mm herein; independently addressable vacuum groove 316.3 for a 200 mm herein; indexing pin mounting holes 310.1, 310.2, and 310.3 herein; baseline pads mounts 312 herein; vacuum supply hole 320.1 for pneumatically coupling the vacuum fitting hole 314.1 to the independently addressable vacuum groove 316.1 for handling a 100 mm wafer; vacuum supply hole 320.2 for pneumatically coupling the vacuum fitting hole 314.2 to the independently addressable vacuum groove 316.2 for handling a 150 mm wafer; and vacuum supply hole 320.3 for pneumatically coupling the vacuum fitting hole 314.3 to the independently addressable vacuum groove 316.3 for handling a 200 mm wafer FIG. 7E illustrates another plan view (side view) of the chuck module 300, which can be configured to include: mounting holes 322 for mounting the assembly and mount 304 to couple the end effector module 400 and the rotary motor 432 to the chuck module 300. FIG. 7F illustrates another plan view (opposite side view) of the chuck module 300. FIG. 7G illustrates another plan view (bottom view) of the chuck module 300.

### Stage Module

The apparatus 100 can be configured with a stage module 500. In some embodiments, the stage module 500 comprises a first stage 502 and a motor coupled thereto configured to the translate the apparatus 100 along a first axis of the apparatus 100. In some embodiments, the stage module 500 comprises a second stage 504 and a motor coupled thereto configured to translate the apparatus 100 along a second axis of the apparatus 100. In some embodiments, the stage module 500 comprises a controller module configured to collectively move the apparatus 100 along the first axis and the second axis thereby moving the apparatus 100 along a motion path between the indexer 1000, the alignment module 600, and the inspection station.

Various figures herein depict the stage module 500. For example, FIG. 9C illustrates the stage module 500 of the apparatus 100, which can be configured to include: the first stage 502 for translating the apparatus 100 along the first axis of the apparatus 100, e.g., (i) toward or away from the indexer 1000, (ii) toward or away from the alignment module 600, or (iii) toward or away from the inspection station; and the second stage 504 for translating the apparatus 100 along the second axis of the apparatus 100, e.g., (i) toward or away from the indexer 1000, (ii) toward or away from the alignment module 600, or (iii) toward or away from the inspection station. By collective operation of the first stage 502 and the second stage 504 of the stage module 500, the apparatus 100 can be configured to move along nonlinear motion paths between the indexer 1000, the alignment module 600, and the inspection station.

### Controller Modules

The apparatus 100 can be configured with one or more controller modules for controlling operations and methods herein of the apparatus 100. In an another aspect, disclosed herein is a method, comprising: (a) providing (1) an end effector module 400 holding a wafer, (2) a chuck module 300, and (3) a pluck module 200 circumscribed by the chuck module 300; (b) with the pluck module 200 extended away from a plane comprising a surface of the chuck module 300, transferring the wafer from the end effector module 400 to the pluck module 200; (c) retracting the pluck module 200 towards the plane such that the wafer comes in contact with the surface of the chuck module 300; and (d) with the wafer in contact with the chuck module 300, inspecting the wafer.

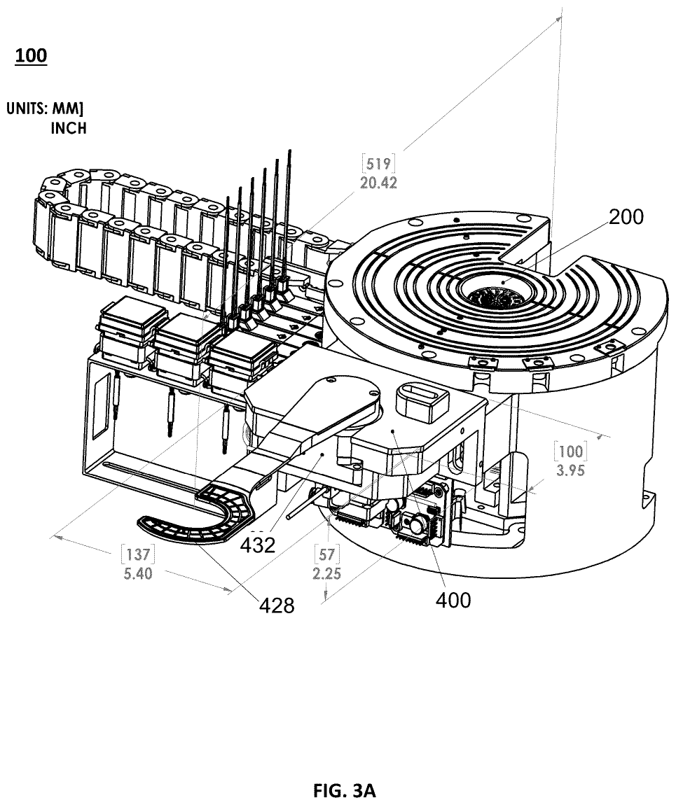

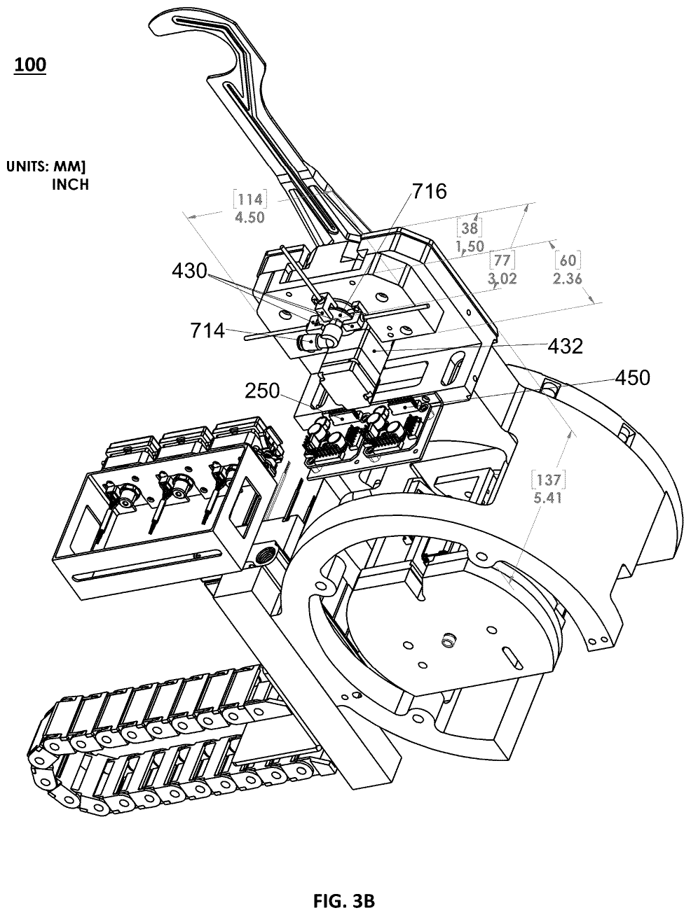

In some cases, one controller module can be configured to control all functions of the apparatus 100. In some cases, two or more controller modules can be configured to control respective functions of the apparatus. For example, FIG. 3B illustrates the controller module 250, which can be configured to control the pluck module 200 of the apparatus 100. For example, FIG. 3B illustrates the controller module 450, which can be configured to control the end effector module 400 of the apparatus 100.

### Training and Operations

The apparatus 100 can be configured with a software module including a graphical user interface 800 (GUI) for training the apparatus 100. The apparatus 100 can be configured with a software module including a graphical user interface 800 (GUI) for operating the apparatus 100. In some embodiments, the apparatus 100 further comprises a graphical user interface 800 (GUI) configured to allow a user to (i) train the apparatus to move along one or more motion paths between one or more positions or (ii) manually control the apparatus to move along the one or more motion paths between the one or more positions.

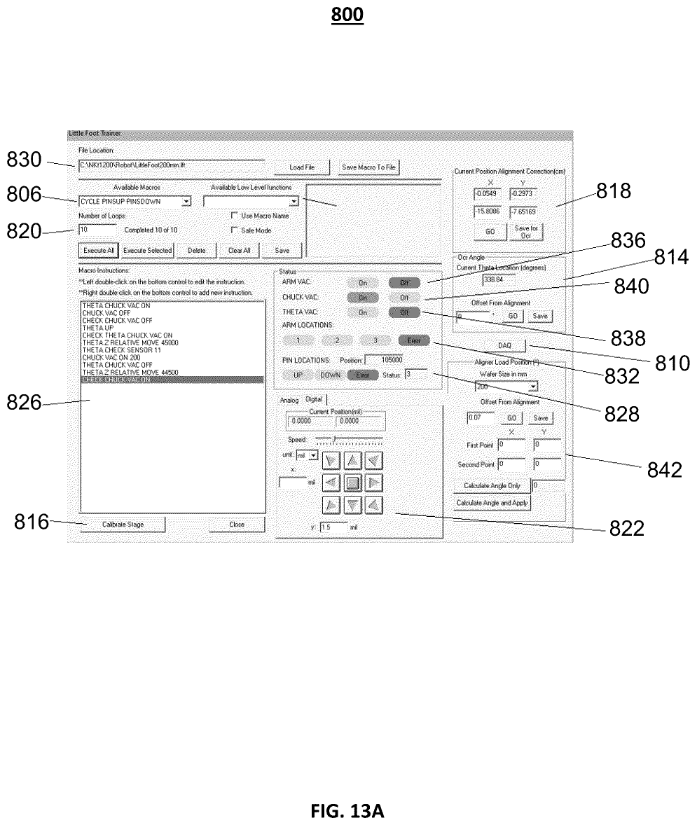

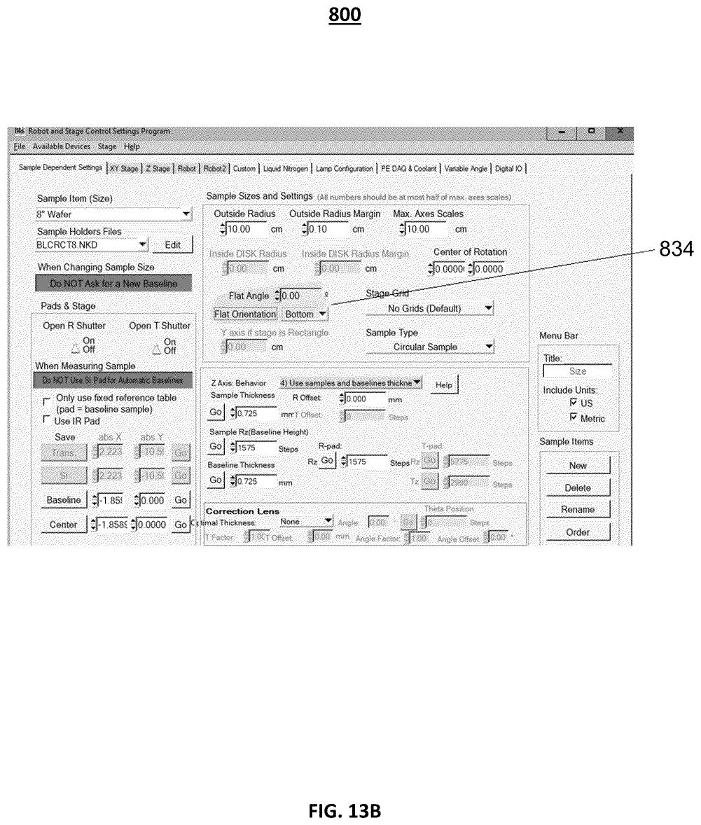

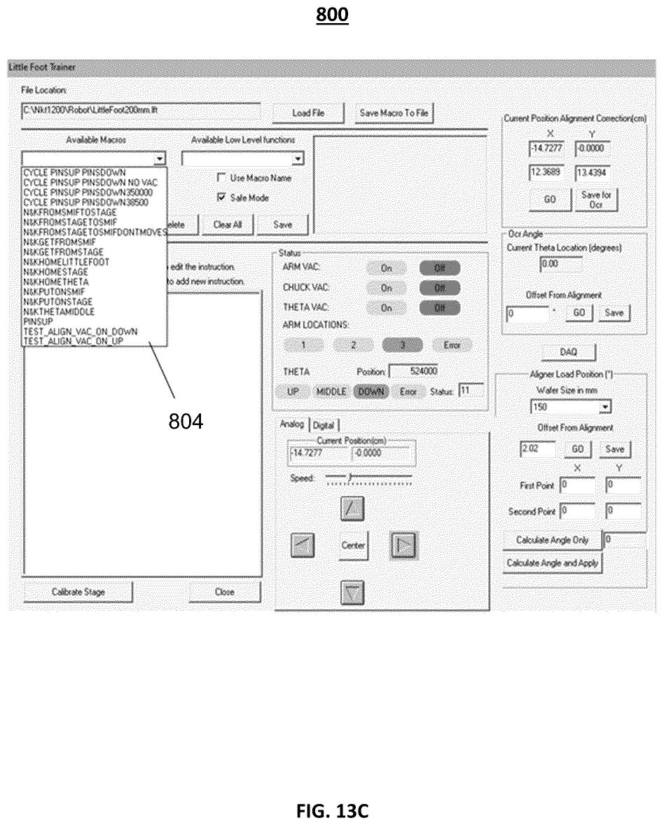

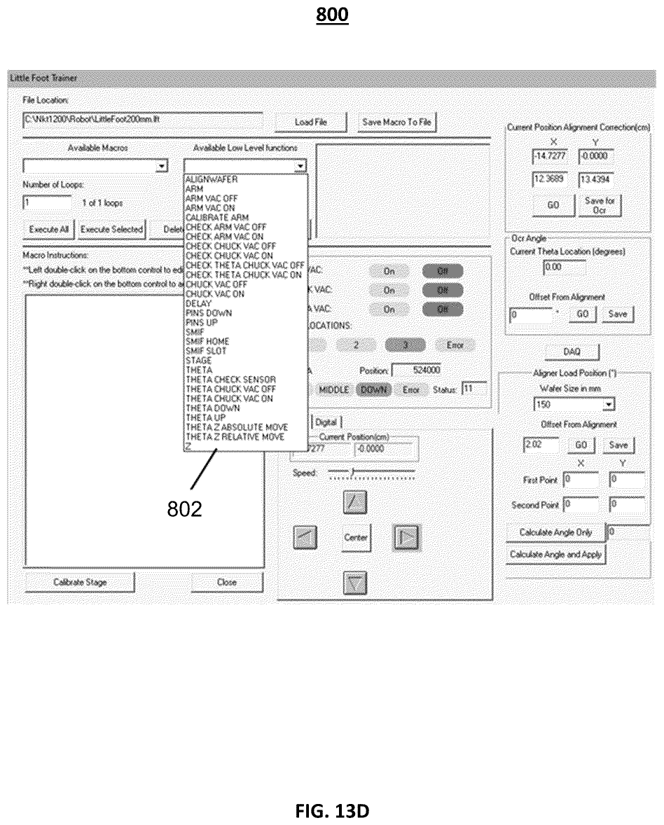

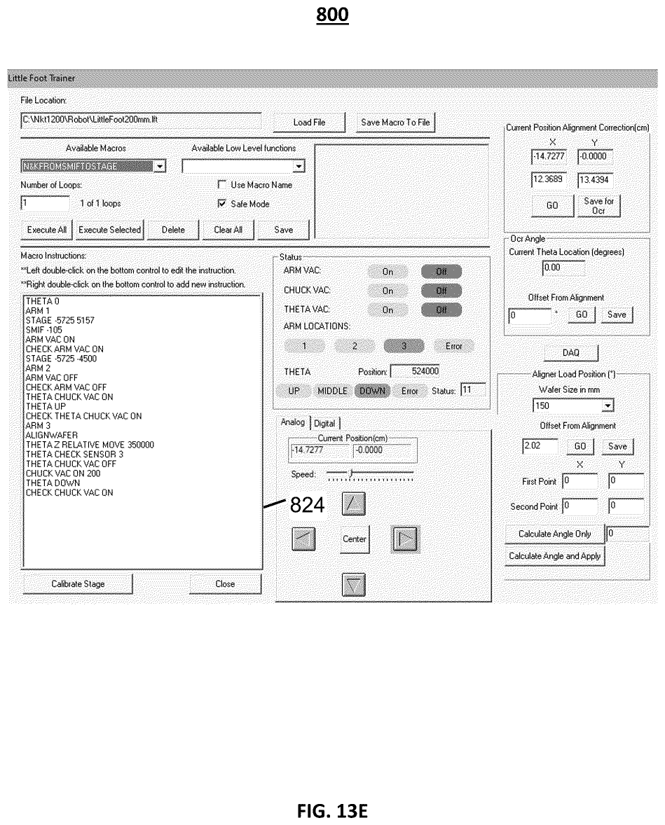

FIGS. 13A-13E illustrate graphical user interfaces (GUIs) of the apparatus 100 to operate or train the apparatus 100 to handle or position a wafer. FIG. 13A illustrates a GUI 800 for operating or training the apparatus 100, which can be configured to include: control 836 for turning a vacuum on and off to the end effector module 400; control 838 for turning a vacuum on and off to the pluck module 200; control 840 for turning a vacuum on and off the chuck module 300; control 832 for rotating the end effector arm module 400; control 828 for moving pluck 206 up and down; control 822 (e.g., a virtual joystick) for translating the stage module 500; control 830 for opening a macro file (e.g., a sequence of commands for executing motion paths of the apparatus 100); control 806 for selecting from a list of macros 804 or functions 802 corresponding to each category of movement for the apparatus 100; control 820 for entering a number of test loops; display 826 for displaying a sequence of low-level commands; control 816 for calibrating the apparatus 100, e.g., the stage module 500; control 818 for entering correction factors for position of the apparatus 100 relative to the indexer 1000, the alignment module 600, or an optical character recognition (OCR) reader; control 814 for angular or position adjustment of the pluck 206 for the OCR reading; control 810 for accessing an data acquisition (DAQ) window or display; and control 842 for angular or position loading of a wafer onto the chuck module 300 and calibration 816.

FIG. 13B illustrates the GUI 800 for operating or training the apparatus 100, which can be configured to include control 834 for selecting the wafer notch or flat orientation when the wafer is placed onto the chuck module 300. FIG. 13C illustrates the GUI 800 for operating or training the apparatus 100, which can be configured to include a display for displaying the list of macros 804. FIG. 13D illustrates the GUI 800 for operating or training the apparatus 100, which can be configured to include a display for displaying the list of functions 802. FIG. 13E illustrates a GUI 800 for operating or training the apparatus 100, which can be configured to include a display for displaying low-level commands for specific macros 804 or functions 802.

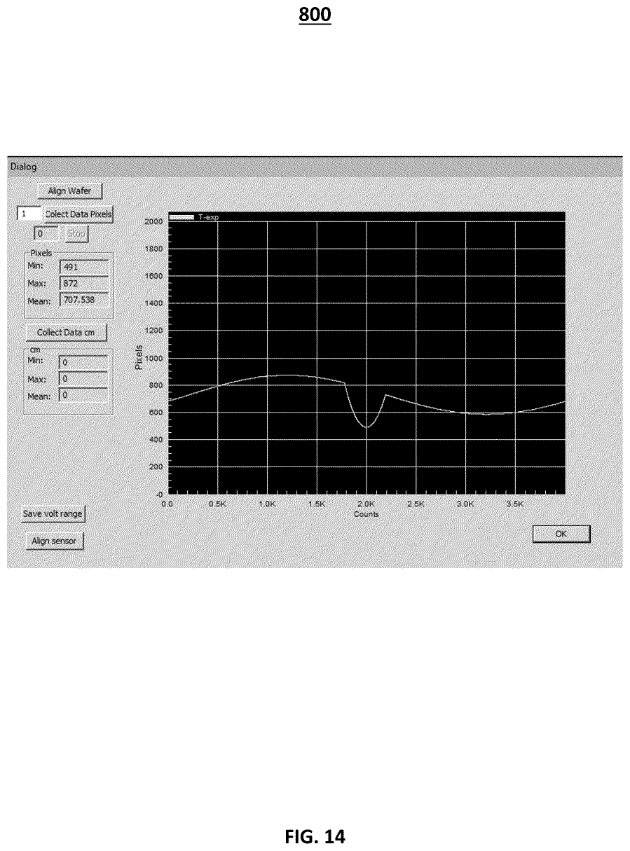

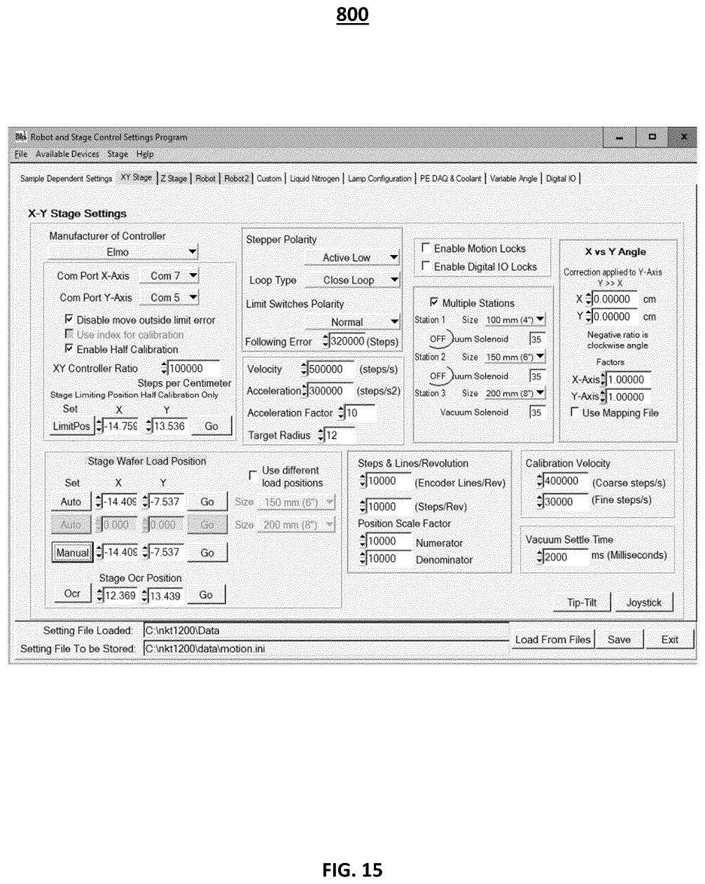

FIG. 14 illustrates the GUI 800 of the apparatus 100 configured to display or determine an alignment of a wafer. FIG. 15 illustrates the GUI 800 of the apparatus 100 for operating or training the stage module 500, and from which various controls can be accessed for operating or training: the pluck module 200, the control board 250, the chuck module 300, the end effector module 400, the control board 450, the stage module 500, the alignment module 600, the vacuum module 700, the power module 900, or the indexer 1000.

### Computing Systems

In an another aspect, disclosed herein is a computer program product for handling or positioning a wafer, the computer program product comprising at least one non-transitory computer-readable medium having computer-readable program code portions embodied therein, the computer-readable program code portions comprising: an executable portion for controlling an end effector module configured to retrieve the wafer from an indexer, wherein the wafer comprises an alignment feature; an executable portion for controlling a pluck module configured to (i) receive the wafer from the end effector module and (ii) rotate the wafer to a predetermined orientation; an executable portion for controlling an alignment module configured to use the alignment feature to determine a virtual center of the wafer during rotation of the wafer by the pluck module; an executable portion for controlling a chuck module configured to releasably hold the wafer after retrieval from the pluck module at the predetermined orientation of the wafer; and an executable portion for controlling a stage module operatively coupled to at least the chuck module, wherein the stage module is configured to move the chuck module proximate to an inspection station based at least on using the virtual center of the wafer.

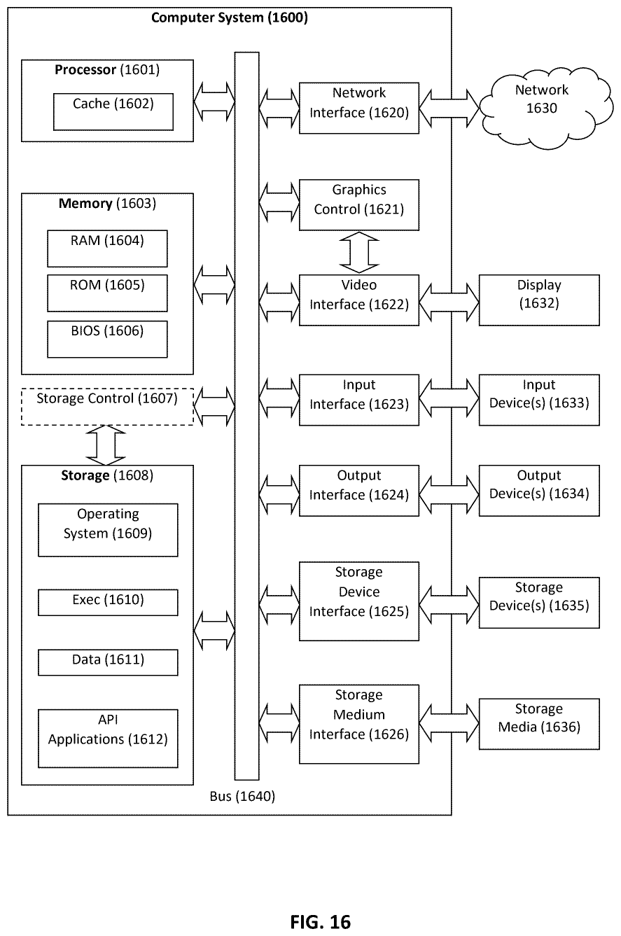

Referring to FIG. 16, a block diagram is shown depicting an exemplary machine that includes a computer system 1600 (e.g., a processing or computing system) within which a set of instructions can execute for causing a device to perform or execute any one or more of the aspects and/or methodologies of the present disclosure. The components in FIG. 16 are examples only and do not limit the scope of use or functionality of any hardware, software, embedded logic component, or a combination of two or more such components implementing particular embodiments.

Computer system 1600 may include one or more processors 1601, a memory 1603, and a storage 1608 that communicate with each other, and with other components, via a bus 1640. The bus 1640 may also link a display 1632, one or more input devices 1633 (which may, for example, include a keypad, a keyboard, a mouse, a stylus, etc.), one or more output devices 1634, one or more storage devices 1635, and various tangible storage media 1636. All of these elements may interface directly or via one or more interfaces or adaptors to the bus 1640. For instance, the various tangible storage media 1636 can interface with the bus 1640 via storage medium interface 1626. Computer system 1600 may have any suitable physical form, including but not limited to one or more integrated circuits (ICs), printed circuit boards (PCBs), mobile handheld devices (such as mobile telephones or PDAs), laptop or notebook computers, distributed computer systems, computing grids, or servers.

Computer system 1600 includes one or more processor(s) 1601 (e.g., central processing units (CPUs) or general purpose graphics processing units (GPGPUs)) that carry out functions. Processor(s) 1601 optionally contains a cache memory unit 1602 for temporary local storage of instructions, data, or computer addresses. Processor(s) 1601 are configured to assist in execution of computer readable instructions. Computer system 1600 may provide functionality for the components depicted in FIG. 16 as a result of the processor(s) 1601 executing non-transitory, processor-executable instructions embodied in one or more tangible computer-readable storage media, such as memory 1603, storage 1608, storage devices 1635, and/or storage medium 1636. The computer-readable media may store software that implements particular embodiments, and processor(s) 1601 may execute the software. Memory 1603 may read the software from one or more other computer-readable media (such as mass storage device(s) 1635, 1636) or from one or more other sources through a suitable interface, such as network interface 1620. The software may cause processor(s) 1601 to carry out one or more processes or one or more steps of one or more processes described or illustrated herein. Carrying out such processes or steps may include defining data structures stored in memory 1603 and modifying the data structures as directed by the software.

The memory 1603 may include various components (e.g., machine readable media) including, but not limited to, a random access memory component (e.g., RAM 1604) (e.g., static RAM (SRAM), dynamic RAM (DRAM), ferroelectric random access memory (FRAM), phase-change random access memory (PRAM), etc.), a read-only memory component (e.g., ROM 1605), and any combinations thereof. ROM 1605 may act to communicate data and instructions unidirectionally to processor(s) 1601, and RAM 1604 may act to communicate data and instructions bidirectionally with processor(s) 1601. ROM 1605 and RAM 1604 may include any suitable tangible computer-readable media described below. In one example, a basic input/output system 1606 (BIOS), including basic routines that help to transfer information between elements within computer system 1600, such as during start-up, may be stored in the memory 1603.

Fixed storage 1608 is connected bidirectionally to processor(s) 1601, optionally through storage control unit 1607. Fixed storage 1608 provides additional data storage capacity and may also include any suitable tangible computer-readable media described herein. Storage 1608 may be used to store operating system 1609, executable(s) 1610, data 1611, applications 1612 (application programs), and the like. Storage 1608 can also include an optical disk drive, a solid-state memory device (e.g., flash-based systems), or a combination of any of the above. Information in storage 1608 may, in appropriate cases, be incorporated as virtual memory in memory 1603.

In one example, storage device(s) 1635 may be removably interfaced with computer system 1600 (e.g., via an external port connector (not shown)) via a storage device interface 1625. Particularly, storage device(s) 1635 and an associated machine-readable medium may provide non-volatile and/or volatile storage of machine-readable instructions, data structures, program modules, and/or other data for the computer system 1600. In one example, software may reside, completely or partially, within a machine-readable medium on storage device(s) 1635. In another example, software may reside, completely or partially, within processor(s) 1601.

Bus 1640 connects a wide variety of subsystems. Herein, reference to a bus may encompass one or more digital signal lines serving a common function, where appropriate. Bus 1640 may be any of several types of bus structures including, but not limited to, a memory bus, a memory controller, a peripheral bus, a local bus, and any combinations thereof, using any of a variety of bus architectures. As an example and not by way of limitation, such architectures include an Industry Standard Architecture (ISA) bus, an Enhanced ISA (EISA) bus, a Micro Channel Architecture (MCA) bus, a Video Electronics Standards Association local bus (VLB), a Peripheral Component Interconnect (PCI) bus, a PCI-Express (PCI-X) bus, an Accelerated Graphics Port (AGP) bus, HyperTransport (HTX) bus, serial advanced technology attachment (SATA) bus, and any combinations thereof.

Computer system 1600 may also include an input device 1633. In one example, a user of computer system 1600 may enter commands and/or other information into computer system 1600 via input device(s) 1633. Examples of an input device(s) 1633 include, but are not limited to, an alpha-numeric input device (e.g., a keyboard), a pointing device (e.g., a mouse or touchpad), a touchpad, a touch screen, a multi-touch screen, a joystick, a stylus, a gamepad, an audio input device (e.g., a microphone, a voice response system, etc.), an optical scanner, a video or still image capture device (e.g., a camera), and any combinations thereof. In some embodiments, the input device is a Kinect®, Leap Motion®, or the like. Input device(s) 1633 may be interfaced to bus 1640 via any of a variety of input interfaces 1623 (e.g., input interface 1623) including, but not limited to, serial, parallel, game port, USB, FIREWIRE, THUNDERBOLT, or any combination of the above.

In particular embodiments, when computer system 1600 is connected to network 1630, computer system 1600 may communicate with other devices, specifically mobile devices and enterprise systems, distributed computing systems, cloud storage systems, cloud computing systems, and the like, connected to network 1630. Communications to and from computer system 1600 may be sent through network interface 1620. For example, network interface 1620 may receive incoming communications (such as requests or responses from other devices) in the form of one or more packets (such as Internet Protocol (IP) packets) from network 1630, and computer system 1600 may store the incoming communications in memory 1603 for processing. Computer system 1600 may similarly store outgoing communications (such as requests or responses to other devices) in the form of one or more packets in memory 1603 and communicated to network 1630 from network interface 1620. Processor(s) 1601 may access these communication packets stored in memory 1603 for processing.

Examples of the network interface 1620 include, but are not limited to, a network interface card, a modem, and any combination thereof. Examples of a network 1630 or network segment 1630 include, but are not limited to, a distributed computing system, a cloud computing system, a wide area network (WAN) (e.g., the Internet, an enterprise network), a local area network (LAN) (e.g., a network associated with an office, a building, a campus or other relatively small geographic space), a telephone network, a direct connection between two computing devices, a peer-to-peer network, and any combinations thereof. A network, such as network 1630, may employ a wired and/or a wireless mode of communication. In general, any network topology may be used.

Information and data can be displayed through a display 1632. Examples of a display 1632 include, but are not limited to, a cathode ray tube (CRT), a liquid crystal display (LCD), a thin film transistor liquid crystal display (TFT-LCD), an organic liquid crystal display (OLED) such as a passive-matrix OLED (PMOLED) or active-matrix OLED (AMOLED) display, a plasma display, and any combinations thereof. The display 1632 can interface to the processor(s) 1601, memory 1603, and fixed storage 1608, as well as other devices, such as input device(s) 1633, via the bus 1640. The display 1632 is linked to the bus 1640 via a video interface 1622, and transport of data between the display 1632 and the bus 1640 can be controlled via the graphics control 1621. In some embodiments, the display is a video projector. In some embodiments, the display is a head-mounted display (HMD) such as a VR headset. In further embodiments, suitable VR headsets include, by way of non-limiting examples, HTC Vive®, Oculus Rift®, Samsung Gear VR®, Microsoft Hololens®, Razer OSVR®, FOVE VR®, Zeiss VR One®, Avegant Glyph®, Freefly VR® headset, and the like. In still further embodiments, the display is a combination of devices such as those disclosed herein.

In addition to a display 1632, computer system 1600 may include one or more other peripheral output devices 1634 including, but not limited to, an audio speaker, a printer, a storage device, and any combinations thereof. Such peripheral output devices may be connected to the bus 1640 via an output interface 1624. Examples of an output interface 1624 include, but are not limited to, a serial port, a parallel connection, a USB port, a FIREWIRE port, a THUNDERBOLT port, and any combinations thereof.

In addition or as an alternative, computer system 1600 may provide functionality as a result of logic hardwired or otherwise embodied in a circuit, which may operate in place of or together with software to execute one or more processes or one or more steps of one or more processes described or illustrated herein. Reference to software in this disclosure may encompass logic, and reference to logic may encompass software. Moreover, reference to a computer-readable medium may encompass a circuit (such as an IC) storing software for execution, a circuit embodying logic for execution, or both, where appropriate. The present disclosure encompasses any suitable combination of hardware, software, or both.

Various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by one or more processor(s), or in a combination of the two. A software module may reside in RAM memory, flash memory, ROM memory, EPROM memory, EEPROM memory, registers, hard disk, a removable disk, a CD-ROM, or any other form of storage medium. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In accordance with the description herein, suitable computing devices include, by way of non-limiting examples, server computers, desktop computers, laptop computers, notebook computers, subnotebook computers, netbook computers, netpad computers, set-top computers, media streaming devices, handheld computers, Internet appliances, mobile smartphones, tablet computers, personal digital assistants, video game consoles, and vehicles. Select televisions, video players, and digital music players with optional computer network connectivity are suitable for use in the system described herein. Suitable tablet computers, in various embodiments, include those with booklet, slate, and convertible configurations.

In some embodiments, the computing device includes an operating system configured to perform executable instructions. The operating system is, for example, software, including programs and data, which manages the device's hardware and provides services for execution of applications. Suitable server operating systems include, by way of non-limiting examples, FreeBSD®, OpenBSD®, NetBSD®, Linux®, Apple® Mac OS X Server®, Oracle Solaris®, Windows Server®, and Novell NetWare®. Suitable personal computer operating systems include, by way of non-limiting examples, Microsoft Windows®, Apple Mac® OS X, UNIX®, and UNIX-like operating systems such as GNU/Linux®. In some embodiments, the operating system is provided by cloud computing. Suitable mobile smartphone operating systems include, by way of non-limiting examples, Nokia Symbian OS, Apple® iOS, Research In Motion BlackBerry® OS, Google® Android®, Microsoft® Windows Phone® OS, Microsoft® Windows Mobile OS, Linux®, and Palm® WebOS. Suitable media streaming device operating systems include, by way of non-limiting examples, Apple TV®, Roku®, Boxee®, Google TV®, Google Chromecast®, Amazon Fire®, and Samsung® HomeSync®. Suitable video game console operating systems include, by way of non-limiting examples, Sony® PS3®, Sony® PS4®, Microsoft® Xbox 360®, Microsoft Xbox One®, Nintendo Wii®, Nintendo Wii U®, and Ouya®. Suitable virtual reality headset systems include, by way of non-limiting example, Meta Oculus®.

### Non-transitory Computer Readable Storage Mediums

In some embodiments, the platforms, systems, media, and methods disclosed herein include one or more non-transitory computer readable storage media encoded with a program including instructions executable by the operating system of an optionally networked computing device. In further embodiments, a computer readable storage medium is a tangible component of a computing device. In still further embodiments, a computer readable storage medium is optionally removable from a computing device. In some embodiments, a computer readable storage medium includes, by way of non-limiting examples, CD-ROMs, DVDs, flash memory devices, solid state memory, magnetic disk drives, magnetic tape drives, optical disk drives, distributed computing systems including cloud computing systems and services, and the like. In some cases, the program and instructions are permanently, substantially permanently, semi-permanently, or non-transitorily encoded on the media.

### Computer Programs

In some embodiments, the platforms, systems, media, and methods disclosed herein include at least one computer program, or use of the same. A computer program includes a sequence of instructions, executable by one or more processor(s) of the computing device's CPU, written to perform a specified task. Computer readable instructions may be implemented as program modules, such as functions, objects, Application Programming Interfaces (APIs), computing data structures, and the like, that perform particular tasks or implement particular abstract data types. In light of the disclosure provided herein, a computer program may be written in various versions of various languages.

The functionality of the computer readable instructions may be combined or distributed as desired in various environments. In some embodiments, a computer program comprises one sequence of instructions. In some embodiments, a computer program comprises a plurality of sequences of instructions. In some embodiments, a computer program is provided from one location. In other embodiments, a computer program is provided from a plurality of locations. In various embodiments, a computer program includes one or more software modules. In various embodiments, a computer program includes, in part or in whole, one or more web applications, one or more mobile applications, one or more standalone applications, one or more web browser plug-ins, extensions, add-ins, or add-ons, or combinations thereof.

### Web Applications

In some embodiments, a computer program includes a web application. In light of the disclosure provided herein, a web application, in various embodiments, utilizes one or more software frameworks and one or more database systems. In some embodiments, a web application is created upon a software framework such as Microsoft®. NET or Ruby on Rails® (RoR). In some embodiments, a web application utilizes one or more database systems including, by way of non-limiting examples, relational, non-relational, object oriented, associative, and XML database systems. In further embodiments, suitable relational database systems include, by way of non-limiting examples, Microsoft® structured query language (SQL) Server, mySQL™, and Oracle®. A web application, in various embodiments, is written in one or more versions of one or more languages. A web application may be written in one or more markup languages, presentation definition languages, client-side scripting languages, server-side coding languages, database query languages, or combinations thereof. In some embodiments, a web application is written to some extent in a markup language such as Hypertext Markup Language (HTML), Extensible Hypertext Markup Language (XHTML), or extensible Markup Language (XML). In some embodiments, a web application is written to some extent in a presentation definition language such as Cascading Style Sheets (CSS). In some embodiments, a web application is written to some extent in a client-side scripting language such as Asynchronous Javascript and XML® (AJAX), Flash Actionscript, Javascript®, or Silverlight®. In some embodiments, a web application is written to some extent in a server-side coding language such as Active Server Pages® (ASP), ColdFusion®, Perl®, Java®, JavaServer Pages® (JSP), Hypertext Preprocessor® (PHP), Python®, Ruby®, Tcl®, Smalltalk®, WebDNA®, or Groovy®. In some embodiments, a web application is written to some extent in a database query language such as Structured Query Language (SQL). In some embodiments, a web application integrates enterprise server products such as IBM Lotus Domino®. In some embodiments, a web application includes a media player element. In various further embodiments, a media player element utilizes one or more of many suitable multimedia technologies including, by way of non-limiting examples, Adobe® Flash®, HTML 5, Apple® QuickTime®, Microsoft Silverlight®, Java®, and Unity®.

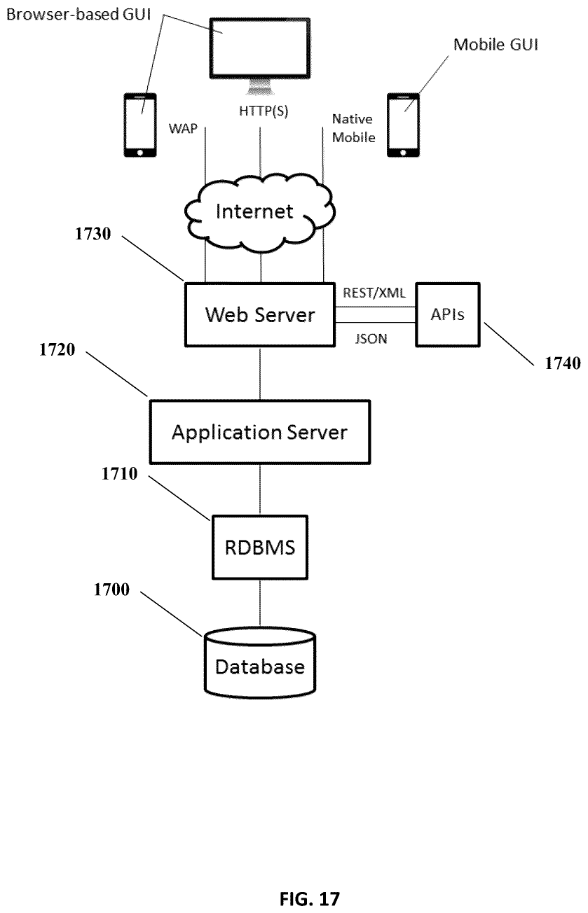

Referring to FIG. 17, in a particular embodiment, an application provision system comprises one or more databases 1700 accessed by a relational database management system (RDBMS) 1710. Suitable RDBMSs include Firebird®, MySQL®, PostgreSQL®, SQLite®, Oracle Database®, Microsoft SQL Server®, IBM DB2®, IBM Informix®, SAP Sybase®, SAP Sybase®, Teradata®, PostGIS®, time-series databases, graph databases, and the like. In this embodiment, the application provision system further comprises one or more application severs 1720 (such as Java® servers,. NET® servers, PHP® servers, and the like) and one or more web servers 1730 (such as Apache®, IIS®, GWS® and the like). The web server(s) optionally expose one or more web services via app application programming interfaces (APIs) 1740. Via a network, such as the Internet, the system provides browser-based and/or mobile native user interfaces.

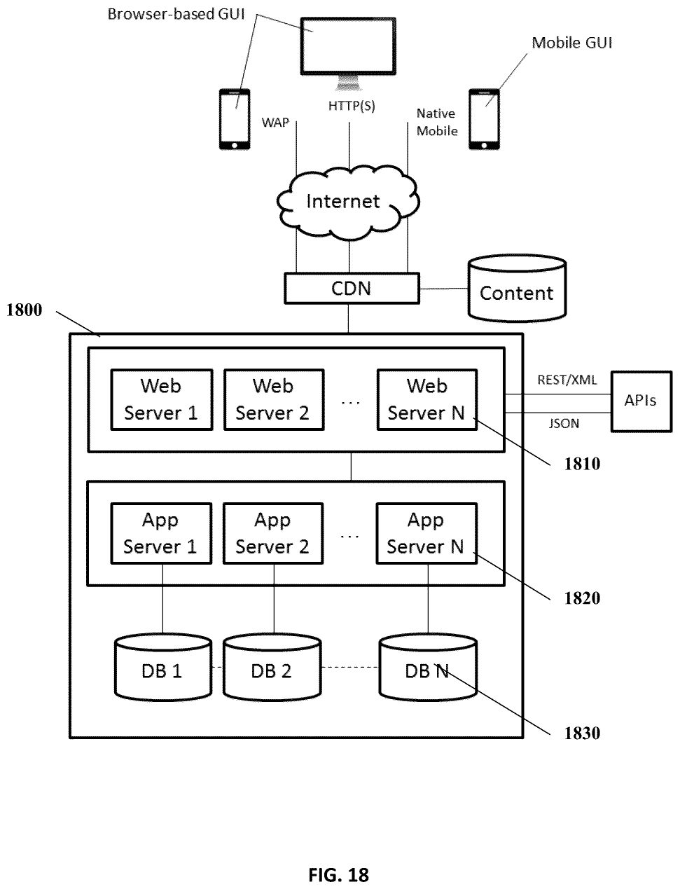

Referring to FIG. 18, in a particular embodiment, an application provision system alternatively has a distributed, cloud-based architecture 1800 and comprises elastically load balanced, auto-scaling web server resources 1810 and application server resources 1820 as well synchronously replicated databases 1830.

### Mobile Applications

In some embodiments, a computer program includes a mobile application provided to a mobile computing device. In some embodiments, the mobile application is provided to a mobile computing device at the time it is manufactured. In other embodiments, the mobile application is provided to a mobile computing device via the computer network described herein.

In view of the disclosure provided herein, a mobile application is created by techniques using hardware, languages, and development environments. Mobile applications are written in several languages. Suitable programming languages include, by way of non-limiting examples, C, C++, C #, Objective-C, Java®, Javascript®, Pascal®, Object Pascal®, Python™, Ruby®, VB. NET®, WML®, and XHTML/HTML with or without CSS, or combinations thereof.

Suitable mobile application development environments are available from several sources. Commercially available development environments include, by way of non-limiting examples, AirplaySDK®, alcheMo®, Appcelerator®, Celsius®, Bedrock®, Flash Lite®, .NET Compact Framework®, Rhomobile®, and WorkLight Mobile Platform®. Other development environments are available without cost including, by way of non-limiting examples, Lazarus®, MobiFlex®, MoSync®, and Phonegap®. Also, mobile device manufacturers distribute software developer kits including, by way of non-limiting examples, iPhone® and iPad® (iOS) SDK, Android® SDK, BlackBerry® SDK, BREW SDK, Palm® OS SDK, Symbian® SDK, webOS® SDK, and Windows® Mobile SDK.

Several commercial forums are available for distribution of mobile applications including, by way of non-limiting examples, Apple® App Store, Google® Play, Chrome® WebStore, BlackBerry® App World, App Store® for Palm devices, App Catalog® for webOS, Windows® Marketplace for Mobile, Ovi Store for Nokia® devices, Samsung® Apps, and Nintendo® DSi Shop.

### Standalone Applications

In some embodiments, a computer program includes a standalone application, which is a program that is run as an independent computer process, not an add-on to an existing process, e.g., not a plug-in. Standalone applications are often compiled. A compiler is a computer program(s) that transforms source code written in a programming language into binary object code such as assembly language or machine code. Suitable compiled programming languages include, by way of non-limiting examples, C, C++, Objective-C®, COBOL®, Delphi®, Eiffel®, Java®, Lisp®, Python®, Visual Basic®, and VB .NET®, or combinations thereof. Compilation is often performed, at least in part, to create an executable program. In some embodiments, a computer program includes one or more executable compiled applications. Additionally, microservices related to Python® and JavaScript® may be used.

### Web Browser Plug-ins

In some embodiments, the computer program includes a web browser plug-in (e.g., web extension, etc.). In computing, a plug-in is one or more software components that add specific functionality to a larger software application. Makers of software applications support plug-ins to enable third-party developers to create abilities which extend an application, to support easily adding new features, and to reduce the size of an application. When supported, plug-ins enable customizing the functionality of a software application. For example, plug-ins are commonly used in web browsers to play video, generate interactivity, scan for viruses, and display particular file types. Several web browser plug-ins may include Adobe Flash Player®, Microsoft Silverlight®, and Apple QuickTime®. In some embodiments, the toolbar comprises one or more web browser extensions, add-ins, or add-ons. In some embodiments, the toolbar comprises one or more explorer bars, tool bands, or desk bands.

In view of the disclosure provided herein, several plug-in frameworks are available that enable development of plug-ins in various programming languages, including, by way of non-limiting examples, C++, Delphi®, Java®, PHP®, Python®, and VB. NET®, or combinations thereof.

Web browsers (also called Internet browsers) are software applications, designed for use with network-connected computing devices, for retrieving, presenting, and traversing information resources on the World Wide Web. Suitable web browsers include, by way of non-limiting examples, Microsoft Internet Explorer®, Mozilla Firefox®, Google Chrome®, Apple Safari®, Opera Software Opera®, and KDE Konqueror®. In some embodiments, the web browser is a mobile web browser. Mobile web browsers (also called microbrowsers, mini-browsers, and wireless browsers) are designed for use on mobile computing devices including, by way of non-limiting examples, handheld computers, tablet computers, netbook computers, subnotebook computers, smartphones, music players, personal digital assistants (PDAs), and handheld video game systems. Suitable mobile web browsers include, by way of non-limiting examples, Google Android® browser, RIM Blackberry® Browser, Apple Safari®, Palm Blazer®, Palm WebOS® Browser, Mozilla Firefox® for mobile, Microsoft Internet Explorer Mobile®, Amazon Kindle Basic Web®, Nokia Browser®, Opera Software Opera Mobile®, and Sony PSP® browser.

### Software Modules

In some embodiments, the platforms, systems, media, and methods disclosed herein include software, server, and/or database modules, or use of the same. In view of the disclosure provided herein, software modules are created by techniques using machines, software, and languages. The software modules disclosed herein are implemented in a multitude of ways. In various embodiments, a software module comprises a file, a section of code, a programming object, a programming structure, or combinations thereof. In further various embodiments, a software module comprises a plurality of files, a plurality of sections of code, a plurality of programming objects, a plurality of programming structures, or combinations thereof. In various embodiments, the one or more software modules comprise, by way of non-limiting examples, a web application, a mobile application, and a standalone application. In some embodiments, software modules are in one computer program or application. In other embodiments, software modules are in more than one computer program or application. In some embodiments, software modules are hosted on one machine. In other embodiments, software modules are hosted on more than one machine. In further embodiments, software modules are hosted on a distributed computing platform such as a cloud computing platform. In some embodiments, software modules are hosted on one or more machines in one location. In other embodiments, software modules are hosted on one or more machines in more than one location.

### Databases

In some embodiments, the platforms, systems, media, and methods disclosed herein include one or more databases (DB), or use of the same. In view of the disclosure provided herein, many databases are suitable for storage and retrieval data. In various embodiments, suitable databases include, by way of non-limiting examples, relational databases, non-relational databases, object oriented databases, object databases, entity-relationship model databases, associative databases, XML databases, time-series databases, graph databases, and the like. Further non-limiting examples include SQL, PostgreSQL®, MySQL®, Oracle®, DB2®, and Sybase. In some embodiments, a database is internet-based. In further embodiments, a database is web-based. In still further embodiments, a database is cloud computing-based. In a particular embodiment, a database is a distributed database. In other embodiments, a database is based on one or more local computer storage devices.

### EXAMPLES

The following illustrative examples are representative of embodiments of systems and methods described herein and are not meant to be limiting in any way.

### Example 1: Improvements Provided by the Apparatus Herein

The apparatus 100 herein can provide improvements and unexpected advantages over other apparatuses for handling, positioning, or aligning wafers. For example, other apparatuses may use a wafer chuck situated on top of a theta stage for rotating a wafer. Such apparatuses may utilize lifting pins (e.g., 3 lifting pins), each of which is attached to a Z actuator and contacts with the wafer for moving the wafer up and down. The theta stage of such apparatuses may be mounted on top of an XY stage. Unfortunately, other apparatus that use this approach can be associated with technical mechanical problems. Such problems can be so severe as to render the performance of the mechanism unsuitable or inoperative. Provided herein are examples of these deficiencies of such apparatuses. For example, one or more of the three pins can periodically jam during its upper Z movements, which can cause the wafer to become unbalanced while positioned on top of the pins. This can cause the end effector to either collide with the wafer or go above the wafer because the wafer has not been fully lifted up above the end effector. For example, the amount of Z movement of each of the three Z actuators may not be identical. This can cause slippage of the wafer when it is placed onto the wafer chuck and also loss of balance of the wafer as the wafer is lifted up and down. For example, the three pins may not be supplied with vacuum while they lift the wafer up and down. This can cause the wafer to slip out of position during its movement. For example, because the three pairs of limit switches which limit Z movement of the pins may be connected in series, if one limit switch gets triggered, the pin associated with it may not stop moving until all other limit switches are triggered. This can cause one or more of the three pins to overshoot resulting in the wafer becoming unbalanced as it is lifted up and down. For example, the pins may often be programmed or trained to a slightly lower Z position for wafer pickup. This can cause the end effector to interfere with the pins. For example, the Z actuators may not have brakes. This can cause the pins to drift downwards due to the weight of the wafer. This issue can become more prominent if the wafer is thicker than Semiconductor Equipment Materials Initiative (SEMI) standards. For example, the diameter of the wafer chuck may be smaller than the size of the wafer that the chuck is designed to handle. This can cause the wafer to overhang at the edge of the chuck resulting in nonuniformity and inaccuracy in the collected measurement data. The wafer can also periodically slip off of its position on the chuck because not the entire wafer is held by vacuum suction. For example, the theta stage assembly may be made of multiple parts, e.g., a rotary motor, bearings, high-tolerance machined parts, and encoders, which may be sandwiched together. Such complicated designs can be prone to failure. Also, poor workmanship can cause the concentricity of its turn table relative to the base of the assembly to be out of specification. This can cause the wafer to wobble during alignment under a wafer alignment sensor resulting in inaccuracy in finding the location of a notch or a flat of the wafer. For example, difficulty of maintenance can result when the entire mechanism has components sandwiched on top of one another. Replacing a part at the bottom of the mechanism can require costly and tedious maintenance due to removing the top components first. Also, wires for the three Z actuators may be soldered together so replacement of one actuator may require resoldering of the wires, which may be prohibited in a semiconductor fabrication facility.

### Example 2: Example Operation of the Apparatus Herein

The apparatus 100 herein can be operated to handle, position, or align wafers. An example operation is provided herein. The end effector arm 400.4 rotates slightly to self-calibrate. Then, the stage module 500 moves the apparatus 100 toward the indexer 1000 with the end effector arm 400.4 coming into the wafer cassette in a straight pick up position. Then, the end effector 400.2 reaches under a wafer inside the cassette to be picked up. The vacuum on the end effector engages. Then, the indexer 1000 slightly moves down for the wafer to contact the end effector 400.2. The end effector 400.2 holds the wafer. Then, the stage module 500 moves the apparatus 100 away from the indexer 1000 until the chuck module 300 reaches the opening window of the alignment module 600. The end effector arm 400.4 remains in its straight position as the stage module 500 moves toward the alignment module 600. Then, the end effector arm 400.4 with the wafer turns 180 degrees so the wafer is right above the pluck 206 of the pluck module 200. Then, the pluck 206 rises. The vacuum on the end effector module 400 disengages. The vacuum on the pluck 206 engages as it contacts the wafer. The pluck 206 continues rising until it lifts the wafer from the end effector 400.2 and holds the wafer. The end effector arm 400.4 then turns 90 degrees away from the pluck module 200 and remains in this position during wafer inspection. Then, the pluck 206 rotates the wafer under the sensor of the alignment module 600 a few times. The notch or flat of the wafer is then found, and the virtual center of the wafer is then determined. Then, the pluck 206 lowers to place the wafer onto the chuck 302 of the chuck module 30. The moment the wafer contacts the chuck 302, the vacuum on the pluck 206 quickly disengages and the vacuum on the chuck 302 quickly engages, thus, ensuring a smooth placement of the wafer onto the chuck 302 without the wafer slipping. Then, the wafer is placed onto the chuck 302 at a designated orientation. The notch or flat of the wafer can be at any orientation depending on a user's input in the software. Then, the stage module 500 moves the chuck module 300 to any location proximate to an inspection area of the inspection station to perform measurements, e.g., metrology. Then, once wafer inspection is complete, the stage module 500 moves the apparatus 100 back to the alignment module 600 to be aligned with a center of the indexer 1000. Then, the vacuum on the chuck 302 disengages; the vacuum on the pluck 206 engages and the pluck 206 then lifts the wafer and rotates it a little. Then, the end effector arm 400.4 turns 90 degrees toward the pluck 206 until its tip is right below the wafer on the pluck 206. The, the pluck 206 lowers the wafer, and its vacuum disengages as the wafer contacts the end effector 400.2. The vacuum on the end effector 400.2 then engages. Then, the end effector 400.2 with the wafer on it rotates 180 degrees and the stage module 500 moves the end effector 400.2 toward the wafer cassette in the indexer 1000 in its straight position. Then, the vacuum on the end effector 400.2 disengages; the indexer 1000 slightly moves up for a cassette slot to contact the wafer on the end effector 400.2. The wafer is now placed onto the cassette slot. The notch or flat on the wafer that has just been placed back to the cassette slot should be facing the same direction as it was when the wafer was initially picked up from the cassette slot. The stage module 500 moves away from the indexer 1000; the apparatus 100 is ready for another sequence set of wafer handling.

### Terms and Definitions

Unless otherwise defined, all technical terms used herein have the same meaning as commonly understood by one of ordinary skill in the art to which this present disclosure belongs.

As used herein, the singular forms “a,” “an,” and “the” include plural references unless the context clearly dictates otherwise. Any reference to “or” herein is intended to encompass “and/or” unless otherwise stated.

As used herein, the term “about” in some cases refers to an amount that is approximately the stated amount.

As used herein, the term “about” refers to an amount that is near the stated amount by 10%, 5%, or 1%, including increments therein.

As used herein, the term “about” in reference to a percentage refers to an amount that is greater or less the stated percentage by 10%, 5%, or 1%, including increments therein.

As used herein, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C”, “one or more of A, B, or C” and “A, B, and/or C” means A alone, B alone, C alone, A and B together, A and C together, B and C together, or A, B and C together.

While preferred embodiments of the present disclosure have been shown and described herein, such embodiments are provided by way of example only. It is not intended that the present disclosure be limited by the specific examples provided within the specification. While the present disclosure has been described with reference to the aforementioned specification, the descriptions and illustrations of the embodiments herein are not meant to be construed in a limiting sense. Numerous variations, changes, and substitutions may occur without departing from the present disclosure. Furthermore, it shall be understood that all aspects of the present disclosure are not limited to the specific depictions, configurations, or relative proportions set forth herein which depend upon a variety of conditions and variables. It should be understood that various alternatives to the embodiments of the present disclosure described herein may be employed in practicing the present disclosure. It is therefore contemplated that the present disclosure shall also cover any such alternatives, modifications, variations, or equivalents. It is intended that the following claims define the scope of the present disclosure and that systems, methods and structures within the scope of these claims and their equivalents be covered thereby.

What is claimed is:

1. An apparatus for positioning a wafer, the apparatus comprising:
an end effector module configured to retrieve the wafer from an indexer, wherein the wafer comprises an alignment feature;
a pluck module configured to (i) receive the wafer from the end effector module and (ii) rotate the wafer to a predetermined orientation;
an alignment module configured to use the alignment feature to determine a virtual center of the wafer during rotation of the wafer by the pluck module;
a chuck module configured to releasably hold the wafer after retrieval from the pluck module at the predetermined orientation of the wafer;
a stage module operatively coupled to at least the chuck module, wherein the stage module is configured to move the chuck module proximate to an inspection station based at least on using the virtual center of the wafer; and
a controller module configured to control at least the end effector module, the pluck module, the chuck module, and the stage module for positioning the wafer.

2. The apparatus of claim 1, wherein the end effector module comprises:
an end effector configured to releasably hold the wafer using a pattern of vacuum grooves operatively coupled to a vacuum source;
an end effector arm configured to mechanically couple the end effector to the apparatus;
a stepper motor operatively coupled the end effector arm and configured to rotate the end effector via the arm;
one or more limit switches configured to limit rotation of the end effector to (i) a predetermined upper limit, (ii) a predetermined lower limit, or (iii) a predetermined intermediate limit; and
a controller module configured to collectively operate the end effector, the end effector arm, the stepper motor, the one or more limit switches, or any combination thereof.

3. The apparatus of claim 2, wherein a vacuum module is configured to control the vacuum source to adjust a vacuum pressure to the pattern of vacuum grooves based at least on a size of the wafer.

4. The apparatus of claim 2, wherein a tip of the end effector has a thickness of at most about 3.0 millimeters (mm), 2.5 mm, 2.0 mm, 1.5 mm, or less.

5. The apparatus of claim 1, wherein the pluck module comprises:
a pluck configured to releasably hold the wafer using a pattern of vacuum grooves operatively coupled to a vacuum source;
a first motor and shaft coupled thereto configured to rotate the pluck around an axis normal to the stage module;
a second motor and shaft coupled thereto configured to translate the pluck along the axis normal to the stage module;
one or more limit switches configured to limit movement of the pluck to (i) a predetermined upper limit, (ii) a predetermined lower limit, or (iii) a predetermined intermediate position;
a brake configured to stop the translation of the pluck along the axis normal to the stage module; and
a controller module configured to collectively operate the pluck, the first motor, the second motor, the one or more limit switches, the brake, the vacuum source, or any combination thereof.

6. The apparatus of claim 5, further comprising one or more linear side carriages and one or more linear side rails configured to collectively constraint translation of the pluck along the axis normal to the stage module.

7. The apparatus of claim 5, wherein the first motor is a stepper motor configured with an embedded rotary incremental non-commutation encoder.

8. The apparatus of claim 5, wherein the second motor is a stepper motor.

9. The apparatus of claim 5, wherein a vacuum module is configured to control the vacuum source to adjust a vacuum pressure to the pattern of vacuum grooves based at least on a size of the wafer.

10. The apparatus of claim 5, wherein the pluck is configured to (i) operate inside a central portion of the chuck module, (ii) extend beyond a plane of the chuck module, (iii) retract to or below the plane of the chuck module, or (iv) any combination of (i)-(iii).

11. The apparatus of claim 5, wherein the pluck is configured to rotate the wafer proximate to the alignment module for obtaining an alignment of the wafer.

12. The apparatus of claim 5, wherein the pluck is configured to:
translate along a central vertical axis of the chuck module; and
rotate around the central vertical axis of the chuck module.

13. The apparatus of claim 5, wherein the pluck is concentrically aligned along a central vertical axis of the chuck module.

14. The apparatus of claim 5, wherein the pluck module is configured to be interchangeable with another pluck module of the same type.

15. The apparatus of claim 1, where the alignment module comprises:
an optical sensor configured to detect the alignment feature; and
a controller module configured to use at least the alignment feature for determining the virtual center of the wafer,
wherein at least the virtual center of the wafer is used to align the wafer to the inspection station.

16. The apparatus of claim 15, wherein the optical sensor comprises a photoelectric sensor.

17. The apparatus of claim 15, wherein the alignment module is configured to be interchangeable with another alignment module of the same type.

18. The apparatus of claim 1, wherein the chuck module comprises:
a chuck configured to releasably hold the wafer using a pattern of independently addressable vacuum grooves operatively coupled to a vacuum source; and
a controller module configured to collectively operate the chuck and the vacuum source.

19. The apparatus of claim 18, wherein a vacuum module is configured to control the vacuum source to adjust a vacuum pressure to each pattern of the pattern of independently addressable vacuum grooves based at least on a size of the wafer.

20. The apparatus of claim 18, wherein a diameter of the chuck is equal to or greater than a diameter of the wafer.

21. The apparatus of claim 18, wherein the chuck is (i) rotationally fixed relative to a vertical axis of the stage module, (ii) translationally fixed relative to a plane of the stage module, or both (i) and (ii).

22. The apparatus of claim 18, wherein the chuck module is configured to be interchangeable with another chuck module of the same type.

23. The apparatus of claim 1, wherein the stage module comprises:
a first stage and a motor coupled thereto configured to the translate the apparatus along a first axis of the apparatus;
a second stage and a motor coupled thereto configured to translate the apparatus along a second axis of the apparatus; and
a controller module configured to collectively move the apparatus along the first axis and the second axis thereby moving the apparatus along a motion path between the indexer, the alignment module, and the inspection station.

24. The apparatus of claim 1, further comprising a power module configured to power the apparatus.

25. The apparatus of claim 1, further comprising a graphical user interface (GUI) configured to allow a user to (i) train the apparatus to move along one or more motion paths between one or more positions or (ii) manually control the apparatus to move along the one or more motion paths between the one or more positions.

26. The apparatus of claim 1, wherein the inspection station is configured to perform metrology comprising thin film measurements or critical dimension measurements.

27. The apparatus of claim 1, wherein the indexer comprises a standard mechanical interface (SMIF) indexer.

28. The apparatus of claim 1, wherein the wafer comprises a fabricated pattern of grating arrays having more than one orientation of the arrays.

29. The apparatus of claim 28, wherein aligning the wafer comprises aligning the wafer to an orientation of the arrays.

30. The apparatus of claim 1, wherein the wafer comprises a fabricated pattern of waveguide structures having more than one orientation of the structures.

31. The apparatus of claim 30, wherein aligning the wafer comprises aligning the wafer to an orientation of the structures.

32. The apparatus of claim 1, wherein the alignment feature comprises a flat of the wafer or a notch of the wafer.

33. The apparatus of claim 1, wherein the apparatus is configured to align the wafer having a thickness of at most about 2.0 millimeters (mm), 1.5 mm, 1.0 mm, 0.5 mm, or less.

34. The apparatus of claim 1, wherein the apparatus is configured to align the wafer having a variation in thickness across a surface of the wafer of at most about 200 micrometers (μm), 150 μm, 100 μm, 50 μm, or less.

35. The apparatus of claim 1, wherein the apparatus is configured to fit inside a portion of the inspection station.

36. A system, comprising:
an end effector module;
a chuck module; and
a pluck module circumscribed by the chuck module, wherein the pluck module is configured to extend away from and retract towards a plane comprising a surface of the chuck module,
wherein the end effector module is configured to direct a wafer to the pluck module after the pluck module is extended away from or above the plane,
wherein the pluck module is configured to retract towards or below the plane to bring the wafer in contact with the surface of the chuck module, and
wherein the chuck module is configured to permit inspection of the wafer when the wafer is in contact with the surface of the chuck module.

37. The system of claim 36, further comprising an alignment module configured to determine a virtual center of the wafer.

38. The system of claim 37, further comprising a stage module configured to move at least the chuck module proximate to an inspection station based at least on using the virtual center of the wafer.

39. The system of claim 38, further comprising a controller module configured to control at least the end effector module, the chuck module, the pluck module, and the stage module.

40. A method, comprising:
(a) providing (1) an end effector module holding a wafer, (2) a chuck module, and (3) a pluck module circumscribed by the chuck module;
(b) with the pluck module extended away from a plane comprising a surface of the chuck module, transferring the wafer from the end effector module to the pluck module;
(c) retracting the pluck module towards the plane such that the wafer comes in contact with the surface of the chuck module; and
(d) with the wafer in contact with the chuck module, inspecting the wafer.

41. A computer program product for positioning a wafer, the computer program product comprising at least one non-transitory computer-readable medium having computer-readable program code portions embodied therein, the computer-readable program code portions comprising:
an executable portion for controlling an end effector module configured to retrieve the wafer from an indexer, wherein the wafer comprises an alignment feature;
an executable portion for controlling a pluck module configured to (i) receive the wafer from the end effector module and (ii) rotate the wafer to a predetermined orientation;
an executable portion for controlling an alignment module configured to use the alignment feature to determine a virtual center of the wafer during rotation of the wafer by the pluck module;
an executable portion for controlling a chuck module configured to releasably hold the wafer after retrieval from the pluck module at the predetermined orientation of the wafer; and
an executable portion for controlling a stage module operatively coupled to at least the chuck module, wherein the stage module is configured to move the chuck module proximate to an inspection station based at least on using the virtual center of the wafer.
